(19) United States
(12) Patent Application Publication
(10) Pub. No.: US 2026/0324062 A1
(43) Pub. Date: Oct. 15, 2026

(54) SEMICONDUCTOR DEVICE INCLUDING MULTIPLE INSULATION PATTERNS AND SURROUNDING GATE ELECTRODE

(71) Applicant: SAMSUNG ELECTRONICS CO., LTD., Suwon-sii (KR)

(72) Inventors: Taeyong KWON, Suwon-si (KR); Yoonjoong KIM, Suwon-si (KR); Sungwoo JANG, Suwon-si (KR)

(73) Assignee: SAMSUNG ELECTRONICS CO., LTD., Suwon-si (KR)

(21) Appl. No.: 19/374,021

(22) Filed: Oct. 30, 2025

(30) Foreign Application Priority Data
Apr. 15, 2025 (KR) 10-2025-0049029

(51) Int. Cl. H10D 84/83; H10D 30/00; H10D 30/01; H10D 30/43; H10D 62/13; H10D 64/23; H10D 64/27; H10D 84/01

(52) U.S. Cl. CPC H10D 84/832; H10D 30/43; H10D 30/503; H10D 30/506; H10D 62/151; H10D 64/256; H10D 64/518; H10D 30/014; H10D 30/0191; H10D 84/0151

(57) ABSTRACT

A semiconductor device includes a substrate having a separation region extending in a first direction. A first active pattern and a second active pattern are disposed on the substrate and spaced apart from each other in a second direction, with the separation region interposed therebetween. First gate electrodes extend in the first direction and cross the first and second active patterns. A first insulation pattern is disposed on the separation region and spaced apart from the first gate electrodes in the second direction. The first insulation pattern includes first extension portions extending in the first direction and spaced apart along the second direction, and a first connection portion disposed between the first extension portions and connecting the first extension portions to each other.

### CROSS-REFERENCE TO RELATED APPLICATIONS

This U.S. non-provisional patent application claims priority under 35 U.S.C. § 119 to Korean Patent Application No. 10-2025-0049029, filed on Apr. 15, 2025, with the Korean Intellectual Property Office, the entire contents of which are hereby incorporated by reference.

### BACKGROUND

The present disclosure relates to a semiconductor device, and in particular to a semiconductor device including a field effect transistor.

The semiconductor device includes an integrated circuit consisting of metal-oxide-semiconductor field-effect transistors (MOSFETs). To meet an increasing demand for a semiconductor device with a small pattern size and a reduced design rule, the MOSFETs are being aggressively scaled down. The scale-down of the MOS-FETs may lead to deterioration in operational properties of the semiconductor device. A variety of studies are being conducted to overcome technical limitations associated with the scale-down of the semiconductor device and to realize high performance semiconductor devices.

### SUMMARY

An embodiment of the inventive concept provides a semiconductor device having improved reliability.

According to an embodiment of the inventive concept, a semiconductor device may comprise a substrate including a separation region extending in a first direction, a first active pattern and a second active pattern on the substrate, the first active pattern and the second active pattern being spaced apart from each other in a second direction perpendicular to the first direction with the separation region therebetween, first gate electrodes crossing the first active pattern and the second active pattern and extending in the first direction, and a first insulation pattern horizontally spaced apart from the first gate electrodes and provided on the separation region, wherein the first insulation pattern comprises first extension portions extending in the first direction and spaced apart from each other along the second direction and a first connection portion provided between the first extension portions and connecting the first extension portions to each other.

According to an embodiment of the inventive concept, a semiconductor device may comprise a substrate including a separation region extending in a first direction, a first active pattern and a second active pattern on the substrate, the first active pattern and the second active pattern being spaced apart from each other in a second direction perpendicular to the first direction with the separation region therebetween, first gate electrodes crossing the first active pattern and the second active pattern and extending in the first direction, a plurality of insulation patterns provided on the separation region and spaced apart from each other; and a second gate electrode provided on the separation region and surrounding the plurality of insulation patterns in a plan view, wherein each of the plurality of insulation patterns comprises extension portions extending in the first direction and spaced apart from each other along the second direction and a connection portion provided between the extension portions and connecting the extension portions to each other.

According to an embodiment of the inventive concept, a semiconductor device may comprise a substrate including a separation region extending in a first direction, a first active pattern and a second active pattern on the substrate, the first active pattern and the second active pattern being spaced apart from each other in a second direction perpendicular to the first direction with the separation region therebetween, first source/drain patterns provided on the first active pattern, second source/drain patterns provided on the second active pattern, a first channel pattern including first semiconductor patterns vertically stacked and spaced apart from each other between the first source/drain patterns, a second channel pattern including second semiconductor patterns vertically stacked and spaced apart from each other between the second source/drain patterns, first gate electrodes extending in the first direction on the first channel pattern and the second channel pattern, active contacts electrically connected with the first source/drain patterns and the second source/drain patterns, gate contacts electrically connected with the first gate electrodes and a first insulation pattern horizontally spaced apart from the first gate electrodes and provided on the separation region, wherein the first insulation pattern comprises first extension portions each extending in the first direction and spaced apart from each other along the second direction and a first connection portion provided between the first extension portions and connecting the first extension portions to each other.

According to an embodiment of the inventive concept, a method of manufacturing a semiconductor device may comprise forming a stacked pattern including sacrificial layers and active layers alternately disposed on a substrate, performing a patterning process on a separation region of the substrate to form a first active pattern and a second active pattern, forming a device isolation layer on the separation region of the substrate, forming first sacrificial patterns extending in a first direction on the first active pattern and the second active pattern, forming a second sacrificial pattern on the device isolation layer on the separation region, forming a first interlayer insulating layer between the first sacrificial patterns and forming a first insulation pattern in an inner region defined by an inner wall of the second sacrificial pattern, wherein the first insulation pattern includes first extension portions extending in the first direction and spaced apart from each other along a second direction perpendicular to the first direction and a first connection portion connecting the first extension portions to each other.

According to some embodiments, the method of manufacturing the semiconductor device may further include removing the first and second sacrificial patterns after forming the first insulation pattern, forming first gate electrodes in a space where the first sacrificial pattern is removed; and forming a second gate electrode in a space where the second sacrificial pattern is removed.

According to some embodiments, the second gate electrode may fill between the first extension portions.

According to some embodiments, the second gate electrode may surround the first insulation pattern in a plan view.

### BRIEF DESCRIPTION OF THE DRAWINGS

FIG. 1 is a plan view of a semiconductor device according to embodiments of the inventive concept.

FIGS. 2A-2D are cross-sectional views of a semiconductor device according to embodiments of the inventive concept, which is taken along line A-A′, line B-B′, line C-C′, and line D-D′ of FIG. 1, respectively.

FIGS. 3A-3C are top views of a semiconductor device according to some embodiments of the inventive concept.

FIGS. 4A and 4B are cross-sectional views of a semiconductor device according to embodiments of the inventive concept, which is taken along line I-I′, line II-II′ of FIG. 3C.

FIGS. 5A to 5D, 6, 7A to 7D, 8A, 8B, 9A, 9B, 10, 11A to 11D, 12, 13A to 13D, 14A to 14C, 15, and 16A to 16D are diagrams illustrating a method of manufacturing a semiconductor device according to some embodiments of the inventive concept.

### DETAILED DESCRIPTION

Hereinafter, a semiconductor device according to embodiments of the present invention will be described in detail with reference to the drawings.

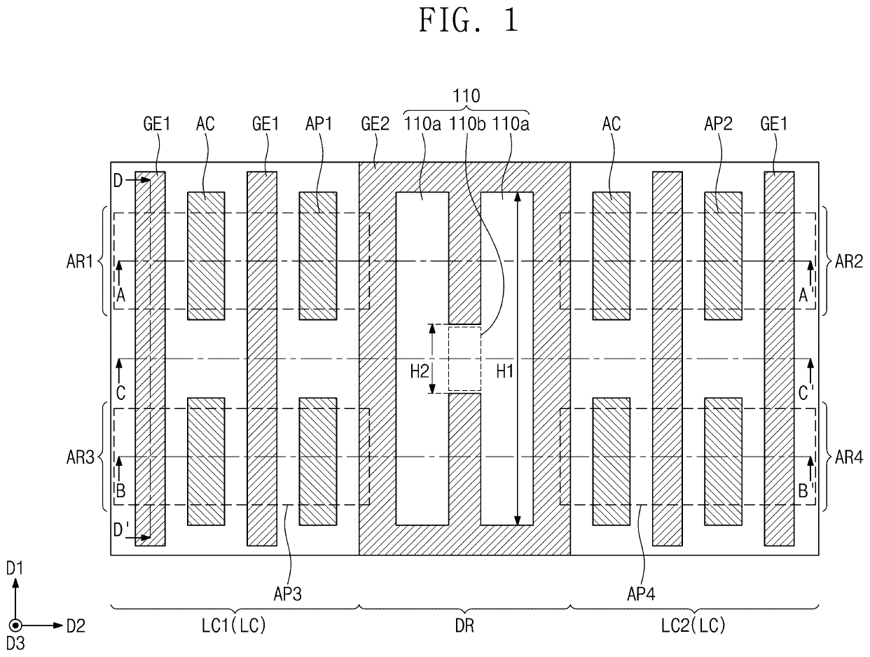

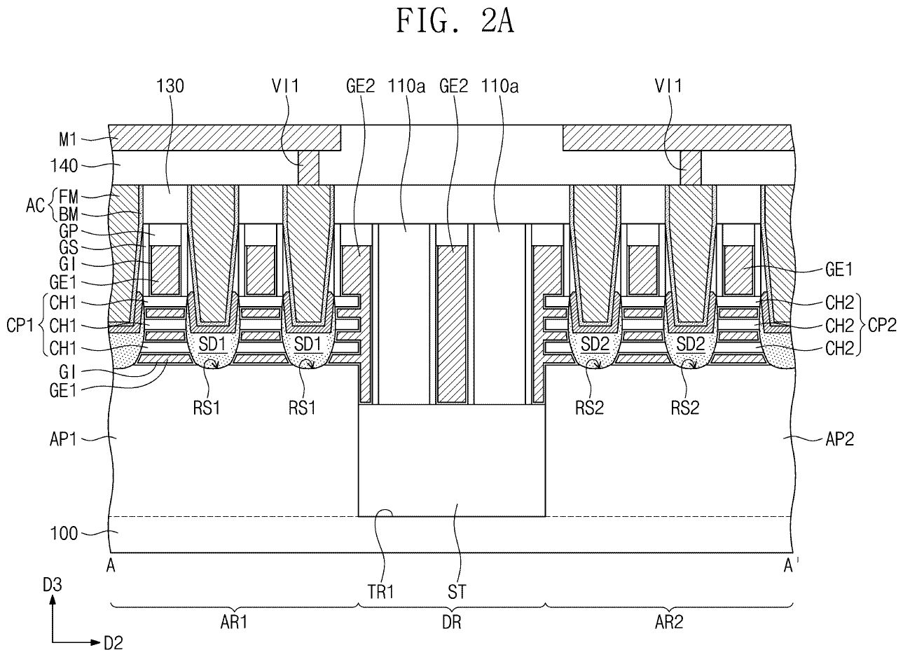

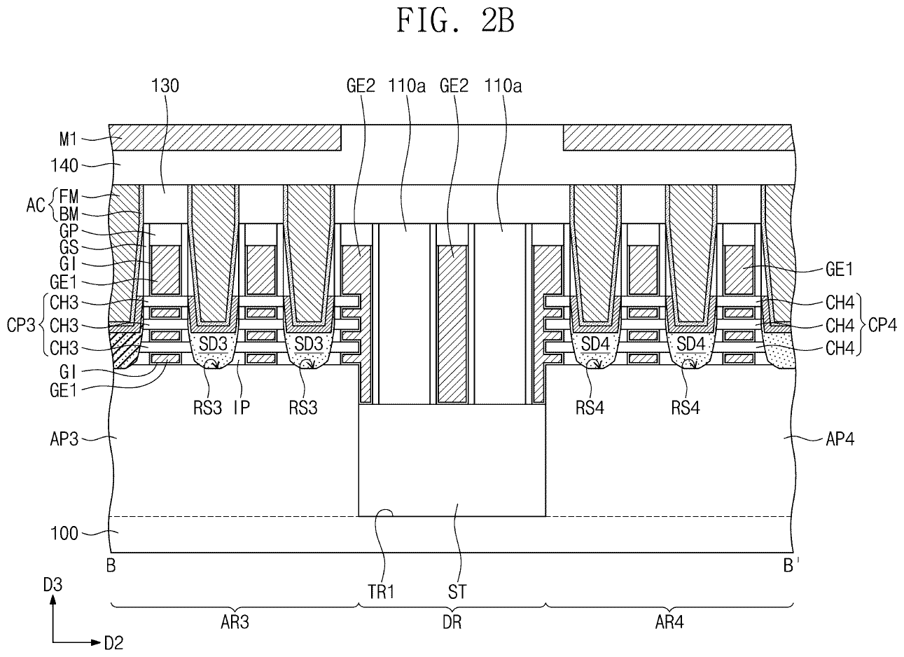

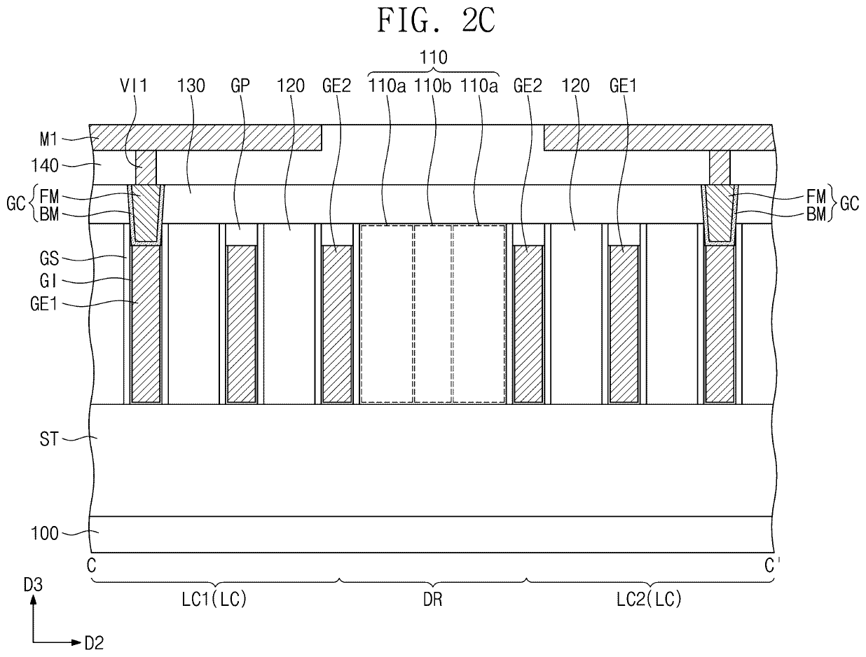

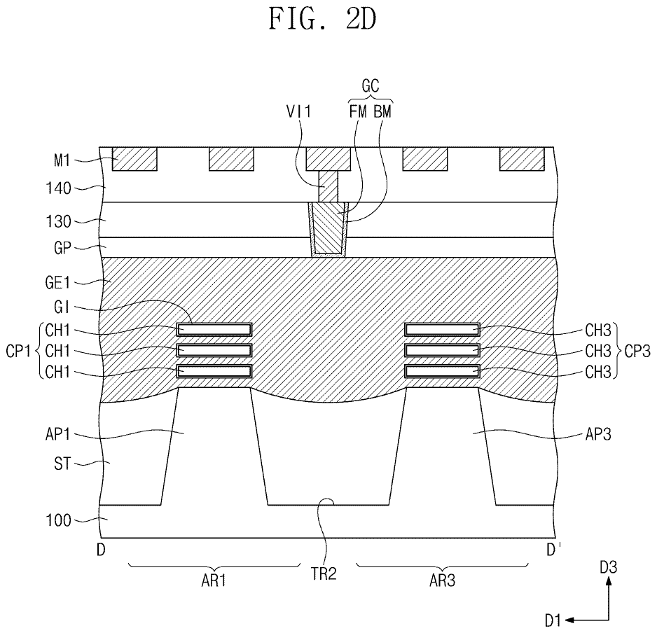

FIG. 1 is a plan view of a semiconductor device according to embodiments of the inventive concept. FIGS. 2A-2D are cross-sectional views of a semiconductor device according to embodiments of the inventive concept, which is taken along line A-A′, line B-B′, line C-C′, and line D-D′ of FIG. 1, respectively.

Referring to FIGS. 1 and 2A-2D, a substrate 100 may be provided. The substrate 100 may be a semiconductor substrate including one of silicon (Si), germanium (Ge), silicon-germanium (SiGe), or a compound semiconductor substrate. For example, the substrate 100 may be a silicon wafer.

The substrate 100 may include a first cell region LC1, a second cell region LC2, and a separation region DR therebetween. Each of the first and second cell regions LC1, LC2 may be a cell region LC in which a logic cell is provided. For example, logic transistors constituting a logic circuit may be provided on the cell regions LC1, LC2. The first cell region LC1 and the second cell region LC2 may be defined by a first trench TR1 formed in the substrate 100. In other words, the separation region DR may refer to a region where the first trench TR1 is formed. The separation region DR and the first trench TR1 may extend along a first direction D1. The first and second cell regions LC1, LC2 may be spaced apart from each other along a second direction D2. In the present specification, the first and second directions D1 and D2 may refer to directions parallel to a lower surface of the substrate 100 and may be orthogonal to each other. A third direction D3 may refer to a direction perpendicular to the lower surface of the substrate 100 and may be orthogonal to the first and second directions D1 and D2.

A first active region AR1 and a third active region AR3 may be provided on the first cell region LC1. A second active region AR2 and a fourth active region AR4 may be provided on the second cell region LC2. The first active region AR1 and the third active region AR3 may be defined by a second trench TR2 formed in the substrate 100. Similarly, although not shown in the drawings, the second active region AR2 and the fourth active region AR4 may be defined by a trench formed on the substrate 100. The second trench TR2 may extend along the second direction D2. The first active region AR1 and the second active region AR2 may be spaced apart from each other along the second direction D2. The third active region AR3 and the fourth active region AR4 may be spaced apart from each other along the second direction D2. For example, the first active region AR1 and the second active region AR2 may be a PMOSFET region, and the third active region AR3 and the fourth active region AR4 may be a NMOSFET region, but the present disclosure is not limited thereto.

A first active pattern AP1 may be provided on the first active region AR1. Similarly, a second active pattern AP2 may be provided on the second active region AR2, a third active pattern AP3 may be provided on a third active region AR3, and a fourth active pattern AP4 may be provided on an active region AR4.

A device isolation layer ST may be provided on the first and second trenches TR1 and TR2. That is, the device isolation layer ST may be provided between the adjacent active patterns AP1, AP2, AP3, and AP4 in the first directions D1 or the second direction D2 to define the first to fourth active patterns AP1, AP2, AP3, and AP4. The device isolation layer ST may include, for example, at least one of a silicon oxide layer, a silicon nitride layer, or a silicon oxynitride layer.

The first to fourth channel patterns CP1, CP2, CP3, and CP4 may be respectively provided on the first to fourth active patterns AP1, AP2, AP3, and AP4. In other words, a first channel pattern CP1 may be provided on the first active pattern AP1, a second channel pattern CP2 may be provided on the second active pattern AP2, a third channel pattern CP3 may be provided on the third active pattern AP3, and a fourth channel pattern CP4 may be provided on the fourth active pattern AP4. Each of the first to fourth channel patterns CP1, CP2, CP3, and CP4 may include stacked semiconductor patterns CH1, CH2, CH3, and CH4. For example, the first channel pattern CP1 may include first semiconductor patterns CH1 stacked vertically, and the second channel pattern CP2 may include second semiconductor patterns CH2 stacked vertically. Similarly, the third channel pattern CP3 may include third semiconductor patterns CH3 stacked vertically, and the fourth channel pattern CP4 may include fourth semiconductor patterns CH4 stacked vertically.

Each of the first to fourth semiconductor patterns CH1, CH2, CH3, and CH4 may include silicon (Si), germanium (Ge), or silicon-germanium (SiGe). For example, each of the first to fourth semiconductor patterns CH1, CH2, CH3, and CH4 may include crystalline silicon, more specifically, single crystal silicon. In an embodiment of the present application, the first to fourth semiconductor patterns CH1, CH2, CH3, and CH4 may be stacked nanosheets.

A first source/drain pattern SD1 may be provided on the first active pattern AP1. A first recess RS1 may be formed on the first active pattern AP1. The first source/drain pattern SD1 may be provided in the first recess RS1. For example, the first source/drain pattern SD1 may be an impurity region of a first conductivity type (e.g., p-type). The first channel pattern CP1 may be interposed between a pair of the first source/drain patterns SD1. In other words, the stacked first semiconductor patterns CH1 may connect the pair of the first source/drain patterns SD1 to each other.

A second source/drain pattern SD2 may be provided on the second active pattern AP2. A second recess RS2 may be formed on the second active pattern AP2. The second source/drain pattern SD2 may be provided in the second recess RS2. For example, the second source/drain pattern SD2 may be an impurity region of a first conductivity type (e.g., p-type). The second channel pattern CP2 may be interposed between a pair of the second source/drain patterns SD2. In other words, the stacked second semiconductor patterns CH2 may connect the pair of the second source/drain patterns SD2 to each other.

A third source/drain pattern SD3 may be provided on the third active pattern AP3. A third recess RS3 may be formed on the third active pattern AP3. The third source/drain pattern SD3 may be provided in the third recess RS3. For example, the third source/drain pattern SD3 may be an impurity region of a second conductivity type (e.g., n-type). The third channel pattern CP3 may be interposed between a pair of the third source/drain patterns SD3. In other words, the stacked third semiconductor patterns CH3 may connect the pair of the third source/drain patterns SD3 to each other.

A fourth source/drain pattern SD4 may be provided on the fourth active pattern AP4. A fourth recess RS4 may be formed on the fourth active pattern AP4. The fourth source/drain pattern SD4 may be provided in the fourth recess RS4. For example, the fourth source/drain pattern SD4 may be an impurity region of a second conductivity type (e.g., n-type). The fourth channel pattern CP4 may be interposed between a pair of the fourth source/drain patterns SD4. In other words, the stacked fourth semiconductor patterns CH4 may connect the pair of the fourth source/drain patterns SD4 to each other.

The first to fourth source/drain patterns SD1, SD2, SD3, SD4 may be epitaxial patterns formed by a selective epitaxial growth (SEG) process. For example, a top surface of each of the first to fourth source/drain patterns SD1, SD2, SD3, and SD4 may be higher than top surfaces of the first to third channel patterns CP1, CP2, CP3, and CP4. For another example, the top surface of at least one of the first to fourth source/drain patterns SD1, SD2, SD3, or SD4 may be located at substantially the same level as the top surfaces of the first to the fourth channel patterns CP1, CP2, CP3, and CP4.

In an embodiment of the present application, the first and second source/drain patterns SD1, SD2 may include a semiconductor element (e.g., SiGe) having a lattice constant greater than a lattice constant of a semiconductor element (for example, Si) of the substrate 100. Thus, the pair of the first source/drain patterns SD1 or the second source/drain pattern SD2 may provide a compressive stress to the first channel pattern CP1 or the second channel pattern CP2 therebetween. The third and fourth source/drain patterns SD3, SD4 may include the same semiconductor element (e.g., Si) as the substrate 100.

First gate electrodes GE1 crossing the first to fourth channel patterns CP1, CP2, CP3, and CP4 and extending in the first direction D1 may be provided on the cell region LC. In other words, the first gate electrodes GE1 may cross the first to fourth active patterns AP1, AP2, AP3, and AP4. Each of the first gate electrodes GE1 may vertically overlap the first to fourth channel patterns CP1, CP2, CP3, and CP4. The first gate electrodes GE1 may be spaced apart from each other in the second direction D2.

The first gate electrodes GE1 may be provided on a top surface, a bottom surface, and both sidewalls of each of the first to fourth semiconductor patterns CH1, CH2, CH3, and CH4. In other words, the first gate electrodes GE1 may surround the first to fourth semiconductor patterns CH1, CH2, CH3, and CH4. That is, a logic transistor according to an embodiment may be a three-dimensional field effect transistor (e.g., MBCFET) in which the first gate electrode GE1 surrounds a channel three-dimensionally.

A second gate electrode GE2 may be provided on the separation region DR. The second gate electrode GE2 may be spaced apart from the first gate electrodes GE1 along the second direction D2. The second gate electrode GE2 may be disposed on the device isolation layer ST provided on the separation region DR. For example, the second gate electrode GE2 may extend in the second direction D2 to vertically overlap the first to fourth active patterns AP1, AP2, AP3, and AP4, but is not limited thereto. That is, a portion of the second gate electrode GE2 may extend between the semiconductor patterns CH1, CH2, CH3, and CH4 adjacent to the separation region DR. The second gate electrode GE2 may cover a portion of upper surfaces of the first and second active patterns AP1 and AP2. The second gate electrode GE2 may be a dummy gate electrode, and a gate contact GC to be described later may not be connected.

The first and second gate electrodes GE1, GE2 may include, for example, at least one of a conductive metal nitride (e.g., titanium nitride or tantalum nitride) or a metal material (e.g., titanium, tantalum, tungsten, copper, or aluminum).

Gate spacers GS may be disposed on both sidewalls of each of the first and second gate electrodes GE1 and GE2. The gate spacers GS may extend in the first direction D1 along the first and second gate electrodes GE1 and GE2. Top surfaces of the gate spacers GS may be located at a higher level than the top surfaces of the first and second gate electrodes GE1 and GE2. Top surfaces of the gate spacers GS may be coplanar with a top surface of a first interlayer insulating layer 120 or a top surface of a first insulation pattern 110, which will be described later.

For example, the gate spacers GS may include at least one of SiCN, SiCON, or SiN. For another example, the gate spacers GS may include a multi-layer composed of at least two of SiCN, SiCON, or SiN.

A gate capping pattern GP may be provided on the first and second gate electrodes GE1 and GE2. The gate capping pattern GP may extend in the first direction D1 along the first and second gate electrodes GE1 and GE2. The gate capping pattern GP may include a material having etching selectivity with respect to the first interlayer insulating layer 120 and the first insulation pattern 110, which will be described later. Specifically, the gate capping pattern GP may include at least one of SiON, SiCN, SiCON, or SiN.

A gate insulating layer GI may be interposed between the first gate electrodes GE1 and the first to fourth channel patterns CP1, CP2, CP3, and CP4, and between the second gate electrode GE2 and the first insulation pattern 110, which will be described later. The gate insulating layer GI may cover a top surface, a bottom surface, and both sidewalls of each of the first to fourth semiconductor patterns CH1, CH2, CH3, and CH4. The gate insulating layer GI may partially cover an upper surface of the device isolation layer ST on the separation region DR. The gate insulating layer GI may cover sidewalls of the semiconductor patterns CH1, CH2, CH3, and CH4 adjacent to the separation region DR.

The gate insulating layer GI may include a silicon oxide layer, a silicon oxynitride layer, and/or a high dielectric layer. The high dielectric layer may include a high dielectric constant material having a higher dielectric constant than that of the silicon oxide layer. For example, the high dielectric constant material may include at least one of hafnium oxide, hafnium silicon oxide, hafnium zirconium oxide, hafnium tantalum oxide, lanthanum oxide, zirconium dioxide, zirconium silicon dioxide, tantalum dioxide, titanium dioxide, barium strontium titanium oxide, barium titanium oxide, strontium aluminum oxide, lithium oxide, aluminum oxide, lead scandium tantalum oxide, or lead zinc niobate.

Inner spacers IP may be interposed between the second source/drain pattern SD2 and the gate insulating layer GI, and between the fourth source/drain pattern SD4 and the gate insulating layer GI. The second source/drain pattern SD2 may be spaced apart from the gate insulating layer GI with the inner spacers IP interposed therebetween. The fourth source/drain pattern SD4 may be spaced apart from the gate insulating layer GI with the inner spacers IP interposed therebetween. The inner spacers IP may be in direct contact with the second source/drain pattern SD2 or the fourth source/drain pattern SD4. For example, the inner spacers IP may include a silicon nitride layer.

The first insulation pattern 110 may be provided on the separation region DR. The first insulation pattern 110 may be provided on a region defined by inner walls of the second gate electrode GE2 on the separation region DR. In other words, the second gate electrode GE2 may be disposed on sidewalls of the first insulation pattern 110 and in a plan view, the second gate electrode GE2 may surround the first insulation pattern 110. The gate insulating layer GI may be interposed between the first insulation pattern 110 and the second gate electrode GE2. For example, a top surface of the first insulation pattern 110 may be substantially coplanar with a top surface of the gate capping pattern GP and top surfaces of the gate spacers GS. For example, the first insulation pattern 110 may include at least one of silicon oxide, silicon nitride, or silicon oxynitride.

The first insulation pattern 110 may include first extension portions 110a and a first connection portion 110b connecting the first extension portions 110a. The first extension portions 110a of the first insulation pattern 110 may extend in the first direction D1 and may be spaced apart from each other along the second direction D2. For example, the first extension portions 110a may be disposed parallel along the second direction D2, and lengths H1 of the first extension portions 110a along the first direction may be substantially equal to each other. The lengths H1 of the first extension portions 110a along the first direction may be greater than the length H2 of the first connection portion 110b along the first direction D1.

The first connection portion 110b of the first insulation pattern 110 may be disposed between the first extension portions 110a and connect the first extension portions 110a to each other. For example, the first connection portion 110b may extend along the second direction D2. For example, the first connection portion 110b may be spaced apart from end portions of the first extension portions 110a along the first direction D1. In other words, the first connection portion 110b may be connected to center portions of the first extension portions 110a. The first insulation pattern 110 may have an H-shape in a plan view. For example, top surfaces of the first extension portions 110a may be substantially coplanar with top surface of the first connection portion 110b.

The second gate electrode GE2 may surround the first extension portions 110a and the first connection portion 110b in a plan view. For example, the second gate electrode GE2 may cover at least a portion of sidewalls of the first extension portions 110a and the first connection portion 110b. The second gate electrode GE2 may be interposed between the first extension portions 110a to fill a space between the first extension portions 110a.

The first interlayer insulating layer 120 may be disposed on the first cell region LC1 and the second cell region LC2. The first interlayer insulating layer 120 may cover the gate spacers GS and the first and second source/drain patterns SD1 and SD2. A top surface of the first interlayer insulating layer 120 may be substantially coplanar with a top surface of the first insulation pattern 110, a top surface of the gate capping pattern GP, and a top surface of the gate spacers GS.

A second interlayer insulating layer 130 covering the first insulation pattern 110 and the gate capping pattern GP may be disposed on the first interlayer insulating layer 120. For example, the first and second interlayer insulating layers 120 and 130 may include at least one of silicon oxide, silicon nitride, or silicon oxynitride.

An active contact AC may be provided to penetrate the first and second interlayer insulating layers 120 and 130. The active contact AC may electrically connect to the first to fourth source/drain patterns SD1, SD2, SD3, and SD4. The active contact AC may be provided on both sides of the first gate electrode GE1, respectively. In a plan view, the active contact AC may have a bar shape extending in the first direction D1.

The active contact AC may be a self-aligned contact. In other words, the active contact AC may be formed in a self-aligned manner using the gate capping pattern GP and the gate spacer GS. For example, the active contact AC may cover at least a portion of a sidewall of the gate spacer GS. Although not shown, the active contact AC may cover a portion of the upper surface of the gate capping pattern GP.

A metal-semiconductor compound layer, e.g., a silicide layer, may be interposed between the active contact AC and the source/drain patterns SD1, SD2, SD3, SD4. The active contact AC may be electrically connected to the source/drain patterns SD1, SD2, SD3, SD4 through the metal-semiconductor compound layer. For example, the metal-semiconductor compound layer may include at least one of titanium-silicide, tantalum-silicide, tungsten-silicide, nickel-silicide, or cobalt-silicide.

A gate contact GC electrically connected to the first gate electrode GE1 through the second interlayer insulating layer 130 and the gate capping pattern GP may be provided. The gate contact GC may be provided on the first cell region LC1 and the second cell region LC2. The gate contact GC may be electrically connected to the first gate electrode GE1, but not to the second gate electrode GE2.

Each of the active contact AC and the gate contact GC may include a conductive pattern FM and a barrier pattern BM surrounding the conductive pattern FM. For example, the conductive pattern FM may include at least one metal of aluminum, copper, tungsten, molybdenum, or cobalt. The barrier pattern BM may cover a sidewall and a bottom surface of the conductive pattern FM. The barrier pattern BM may include a metal layer/metal nitride layer. For example, the metal layer may include at least one of titanium, tantalum, tungsten, nickel, cobalt, or platinum. For example, the metal nitride layer may include at least one of a titanium nitride layer (TiN), a tantalum nitride layer, a tungsten nitride layer WN, a nickel nitride layer NiN, a cobalt nitride layer CoN, or a platinum nitride layer PtN.

A third interlayer insulating layer 140 may be provided on the second interlayer insulating layer 130. First wirings M1 and first vias VI1 may be provided in the third interlayer insulating layer 140. As an example, the first wirings M1 may extend in the first direction D1. The first wirings M1 may be arranged along the first direction D1 and/or the second direction D2. The first vias VI1 may be provided between the first wirings M1 and the active contacts AC, and between the first wirings M1 and the gate contacts GC to electrically connect them to each other. For example, the third interlayer insulating layer 140 may include at least one of silicon oxide, silicon nitride, or silicon oxynitride.

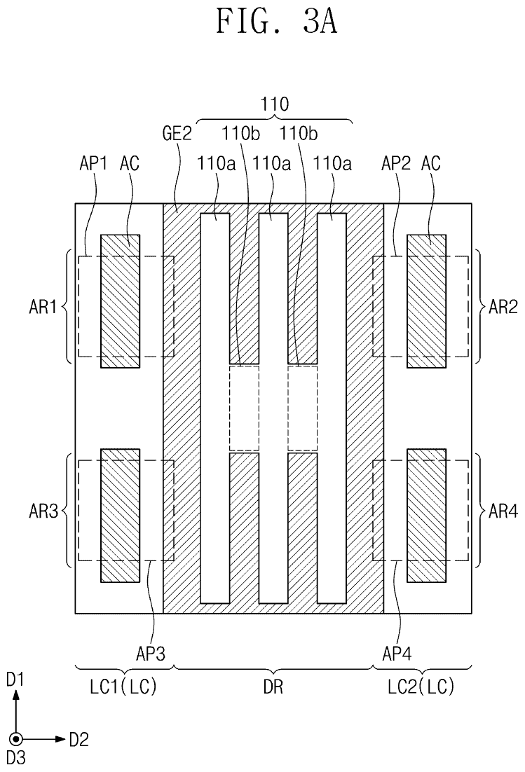

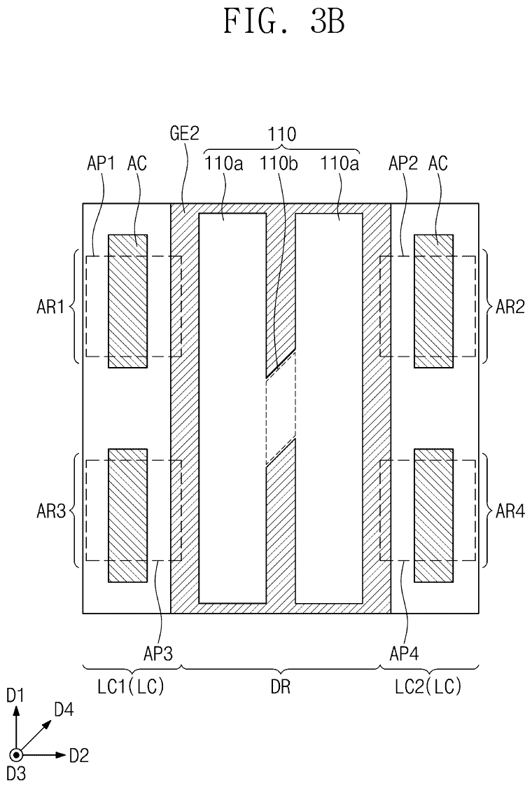

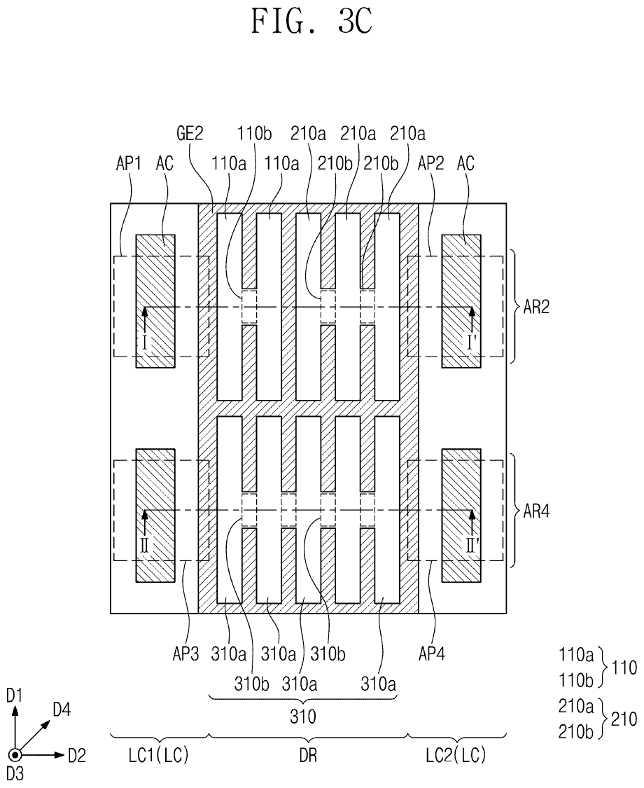

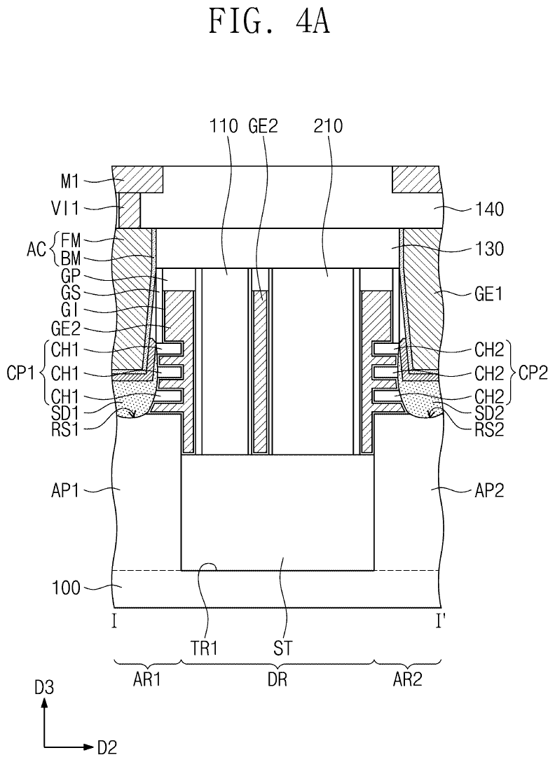

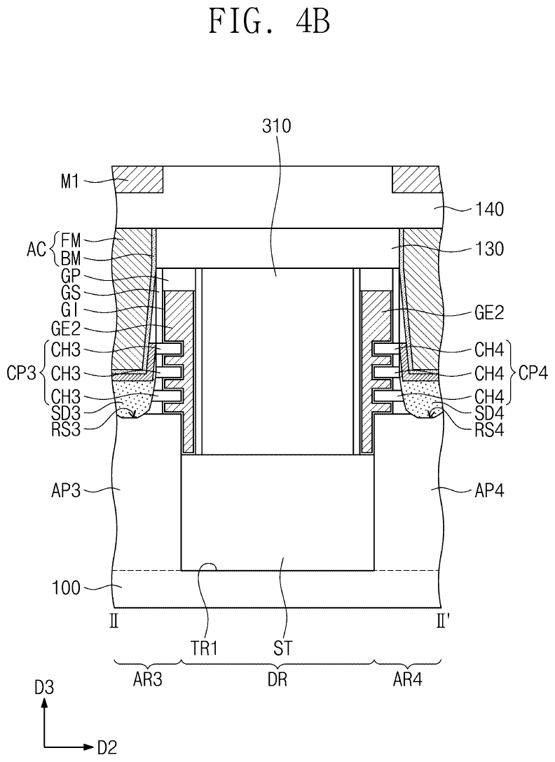

FIGS. 3A-3C are top views of a semiconductor device according to some embodiments of the inventive concept. FIGS. 4A and 4B are cross-sectional views of a semiconductor device according to embodiments of the inventive concept, which is taken along line I-I′, line II-II′ of FIG. 3C. In order to simplify the description, duplicate description will be omitted, and differences from the above will be mainly described.

Referring to FIG. 3A, the first insulation pattern 110 may include a plurality of first extension portions 110a and a plurality of first connection portions 110b. The plurality of first extension portions 110a and the plurality of first connection portions 110b may be alternately arranged along the second direction D2. For example, the plurality of first extension portions 110a may be spaced apart from each other along the second direction D2 and may each extend along the first direction D1. The plurality of first connection portions 110b may be disposed between a pair of adjacent first extension portions 110a along the second direction D2. A length of each of the plurality of first extension portions 110a in the first direction D1 may be greater than a length of each of a plurality of first connection portions 110b in the first direction D1.

Referring to FIG. 3A, the first insulation pattern 110 may include three first extension portions 110a and two first connection portions 110b, but the present disclosure is not limited thereto. For another example, the first insulation pattern 110 may include four or more first extension portions 110a and three or more first connection portions 110b.

Referring to FIG. 3B, the first insulation pattern 110 may include a first connection portion 110b extending along the fourth direction D4. In other words, the first connection portion 110b may extend along the fourth direction D4 between a pair of first extension portions 110a. The fourth direction D4 forms an acute angle with the first direction D1 and the second direction D2 and may be parallel to the lower surface of the substrate 100.

Referring to FIGS. 3C, 4A, and 4B, a plurality of insulation patterns 110, 210, and 310 may be disposed on the separation region DR. The plurality of insulation patterns 110, 210, 310 may be disposed spaced apart from each other. Each of the plurality of insulation patterns 110, 210, 310 may include extension portions 110a, 210a, 310a, and connection portions 110b, 210b, 310b. In each of the plurality of insulation patterns, the extension portions 110a, 210a, 310a may extend along the first direction D1 and may be spaced apart from each other along the second direction D2. The connection portions 110b, 210b, 310b may be provided between the extension portions 110a, 210a, 310a to connect the extension portions 110a, 210a, 310a to each other, respectively. For example, an upper surface of each of the plurality of insulation patterns 110, 210, and 310 may be coplanar with an upper surface of the gate capping pattern GP.

The second gate electrode GE2 may surround the plurality of insulation patterns 110, 210, and 310 in a plan view. The second gate electrode GE2 may be interposed between the plurality of insulation patterns 110, 210, and 310.

Specifically, the plurality of insulation patterns 110, 210, 310 may include a first insulation pattern 110, a second insulation pattern 210, and a third insulation pattern 310. Referring to FIG. 3C, the first insulation pattern 110 and the second insulation pattern 210 may be spaced apart from each other along the second direction D2, and the third insulation pattern 310 may be spaced away from the first and second insulation patterns 110, 210 along the first direction D1. For example, a length of the first insulation pattern 110 along the second direction D2 may be different from a length of the second insulation pattern 210 along the second direction D2 and a length of the third insulation pattern 310 along the second direction D2.

The first insulation pattern 110 may include first extension portions 110a extending in the first direction D1 and a first connection portion 110b connecting the first extension portions 110a. The first extension portions 110a may be spaced apart from each other along the second direction D2, and the first connection portion 110b may be disposed between the first extension portions 110a to connect the first extension portions 110a. A length of each of the first extension portions 110a along the first direction D1 may be greater than a length of the first connection portion 110b along the first direction D1.

The second insulation pattern 210 may include second extension portions 210a extending in the first direction D1 and second connection portions 210b connecting the second extension portions 210a. The second extension portions 210a may be spaced apart from each other along the second direction D2. The second connection portions 210b may be disposed between the second extension portions 210a and connect the second extension portions 210a. For example, the second extension portions 210a and the second connection portions 210b may be alternately disposed along the second direction D2. A length of each of the second extension portions 210a along the first direction D1 may be greater than a length of each the second connection portions 210b along the first direction D1.

The third insulation pattern 310 may include third extension portions 310a extending in the first direction D1 and third connection portions 310b connecting the third extension portions 310a. The third extension portions 310a may be spaced apart from each other along the second direction D2. The third connection portions 310b may be disposed between the third extension portions 310a and connect the third extension portions 310a. For example, the third extension portions 310a and the third connection portions 310b may be alternately disposed along the second direction D2. A length of each of the third extension portions 310a along the first direction D1 may be greater than a length of each the third connection portions 310b along the first direction D1.

The first extension portions 110a of the first insulation pattern 110 may be spaced apart from the second extension portions 210a of the second insulation pattern 210 in the second direction D2. For example, the length of each of the first extension portions 110a along the first direction D1 may be substantially the same as the length of each the second extension portions 210a in the first direction D1. Further, the first extension portions 110a of the first insulation pattern 110 may be disposed parallel to the second extension portions 210a of the second insulation pattern 210.

The first extension portions 110a of the first insulation pattern 110 and the second extension portions 210a of the second insulation pattern 210 may be spaced apart from the third extension portions 310a of the third insulation pattern 310 in the first direction D1.

The second gate electrode GE2 may fill between the first insulation pattern 110 and the second insulation pattern 210, and between the first and second insulation patterns 110 and 210 and the third insulation pattern 310. The second gate electrode GE2 may surround sidewalls of the first insulation pattern 110, the second insulation pattern 210, and the third insulation pattern 310.

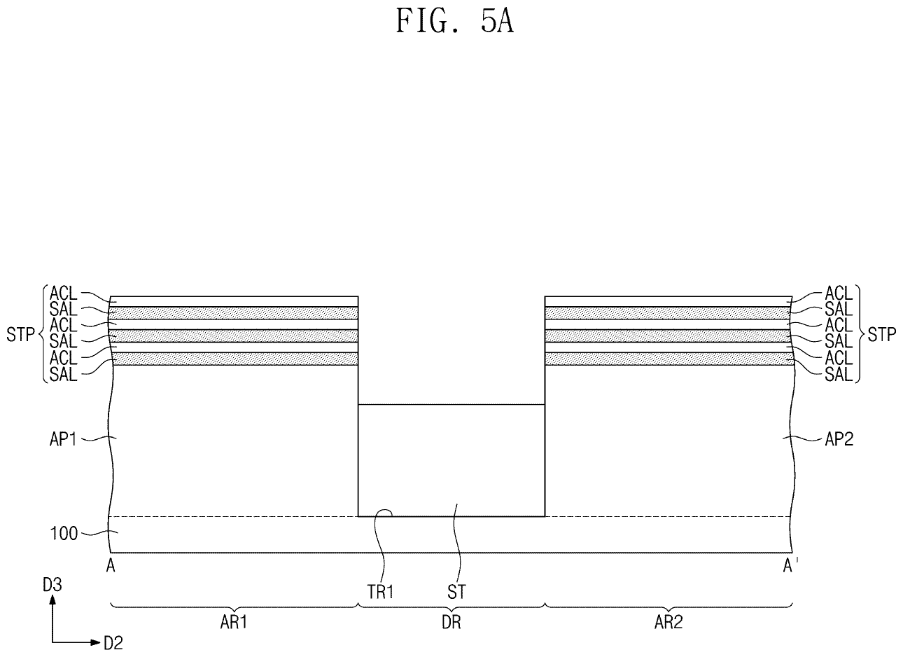

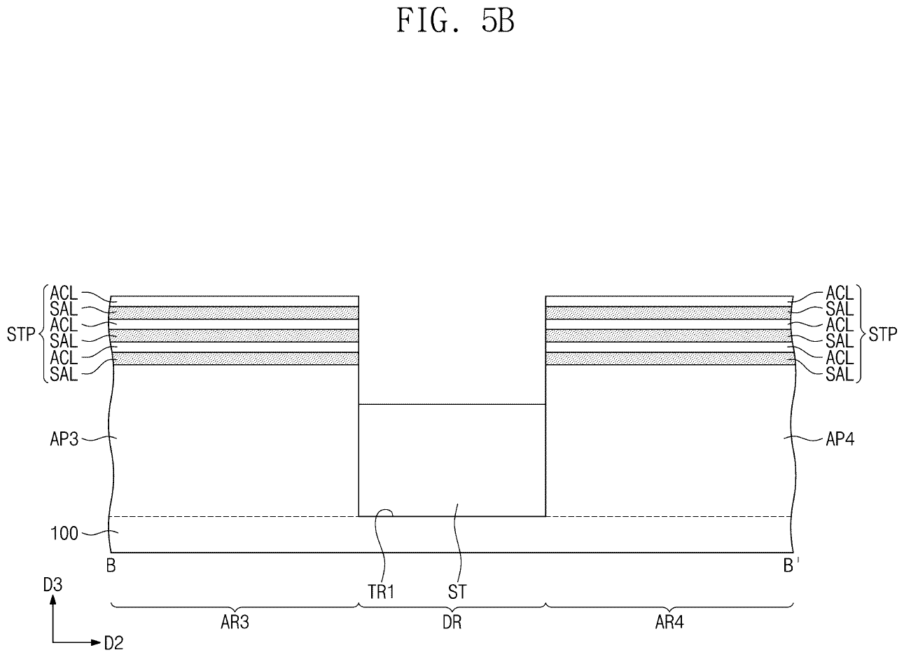

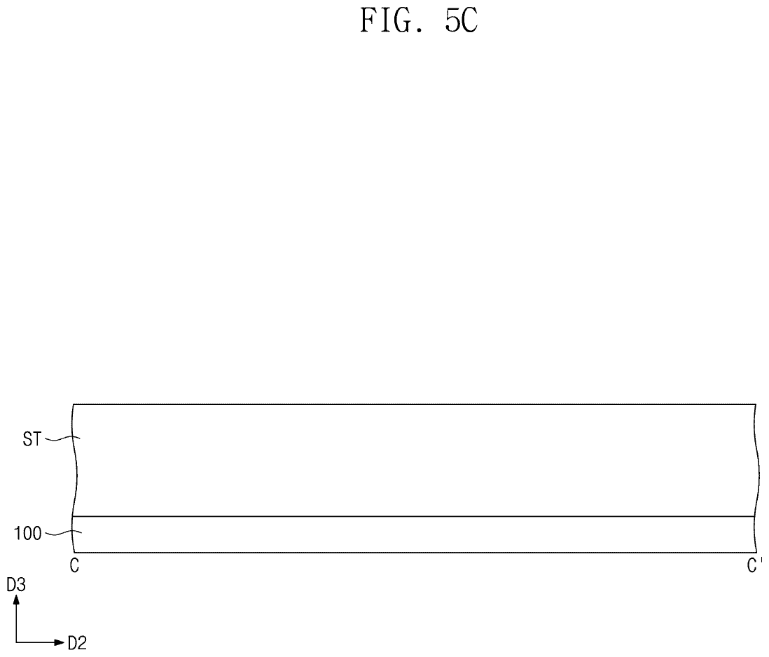

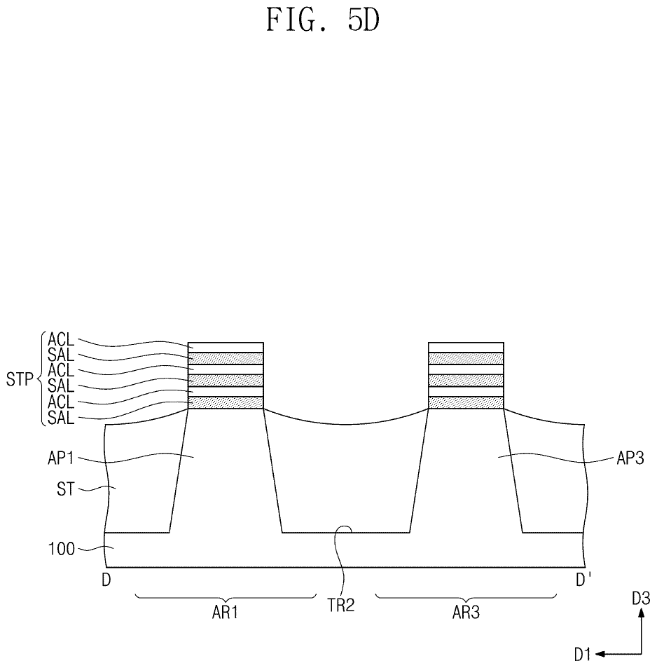

FIGS. 5A to 5D, 6, 7A to 7D, 8A, 8B, 9A, 9B, 10, 11A to 11D, 12, 13A to 13D, 14A t 14C, 15, and 16A to 16D are diagrams illustrating a method of manufacturing a semiconductor device according to some embodiments of the inventive concept.

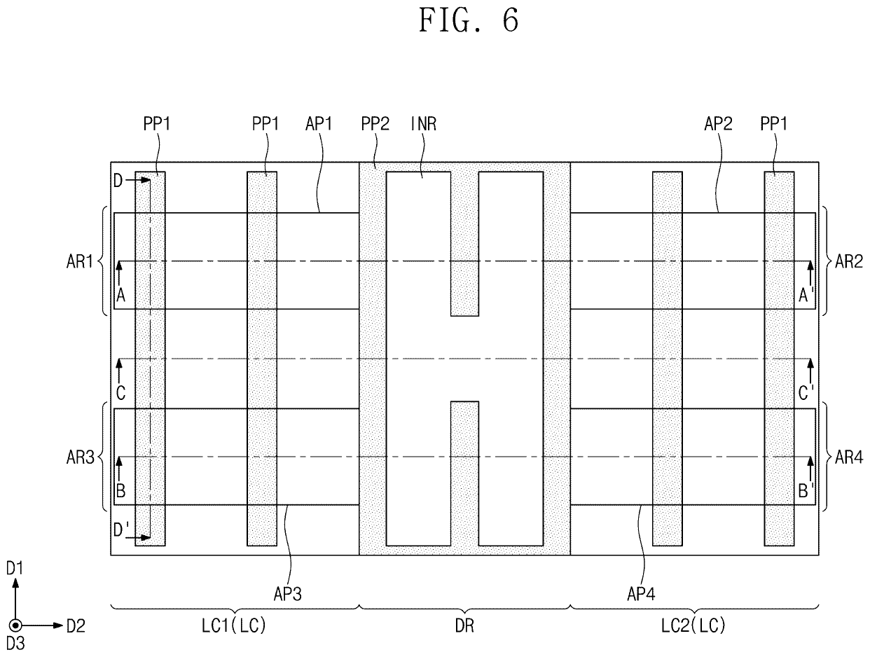

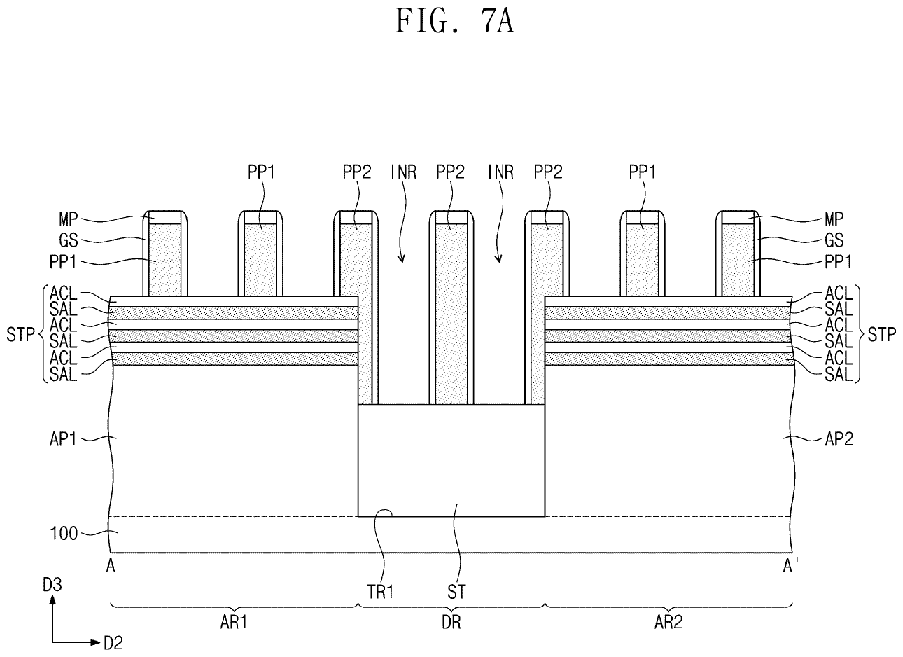

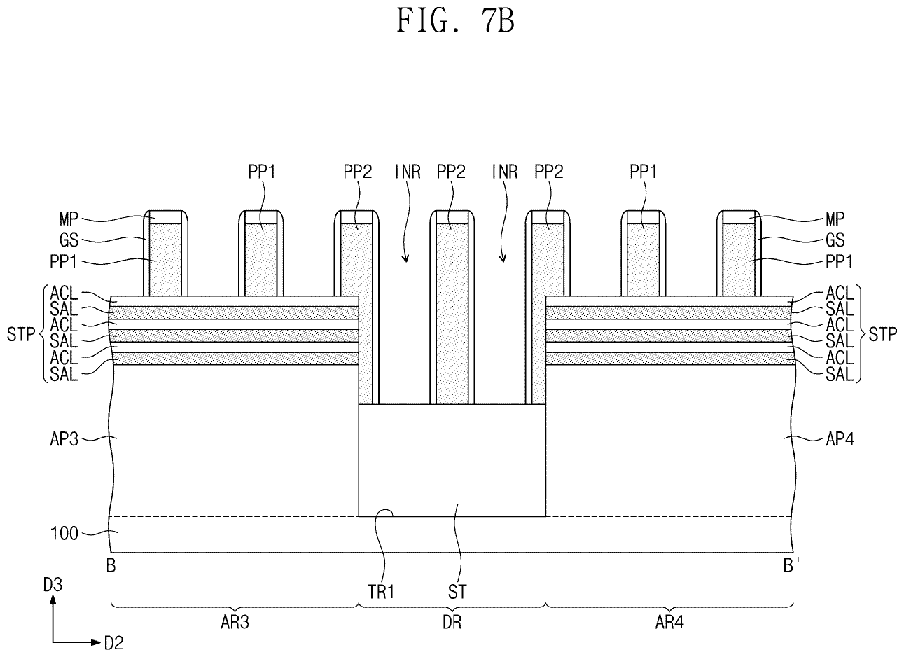

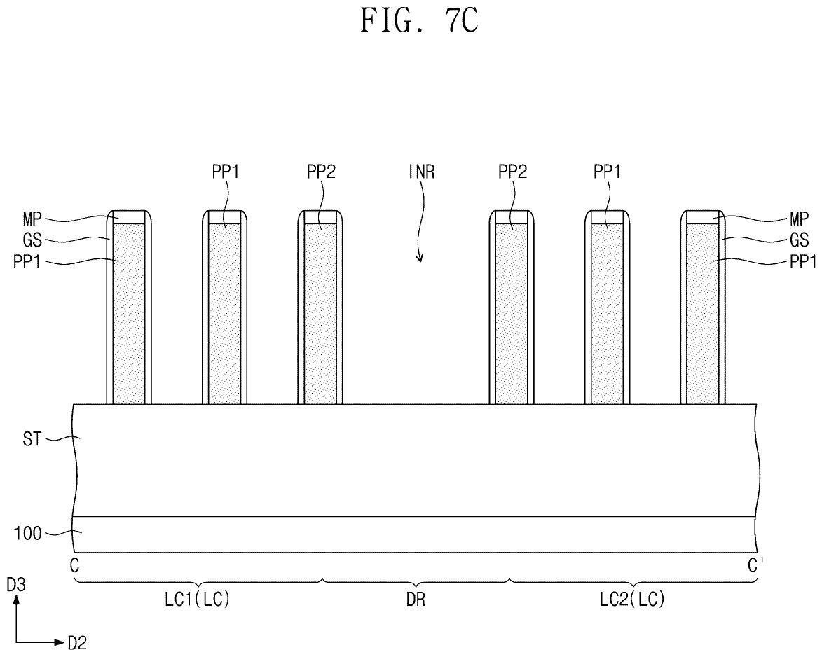

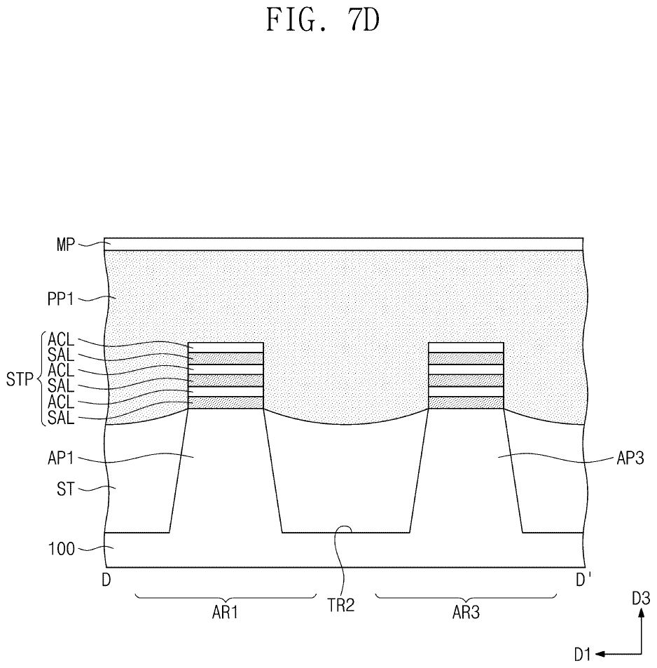

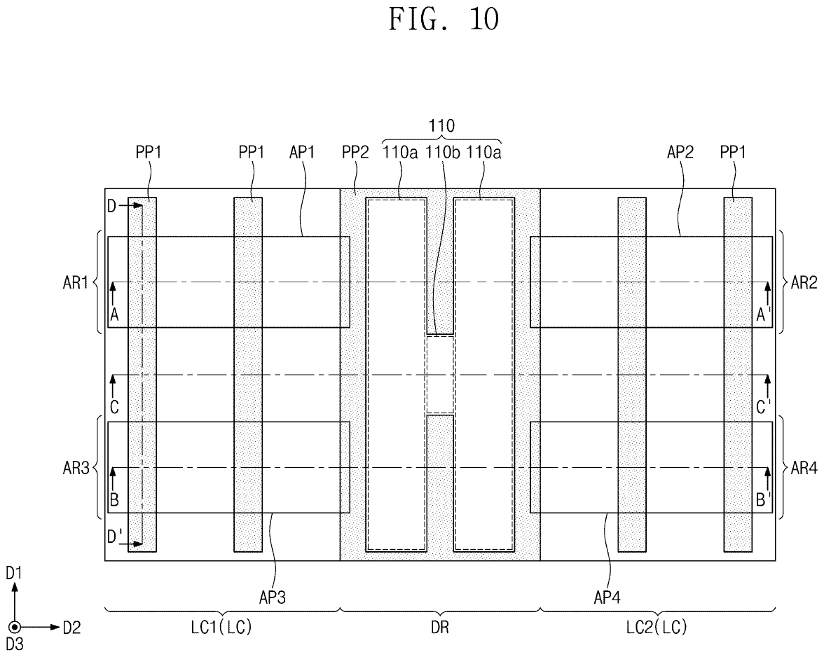

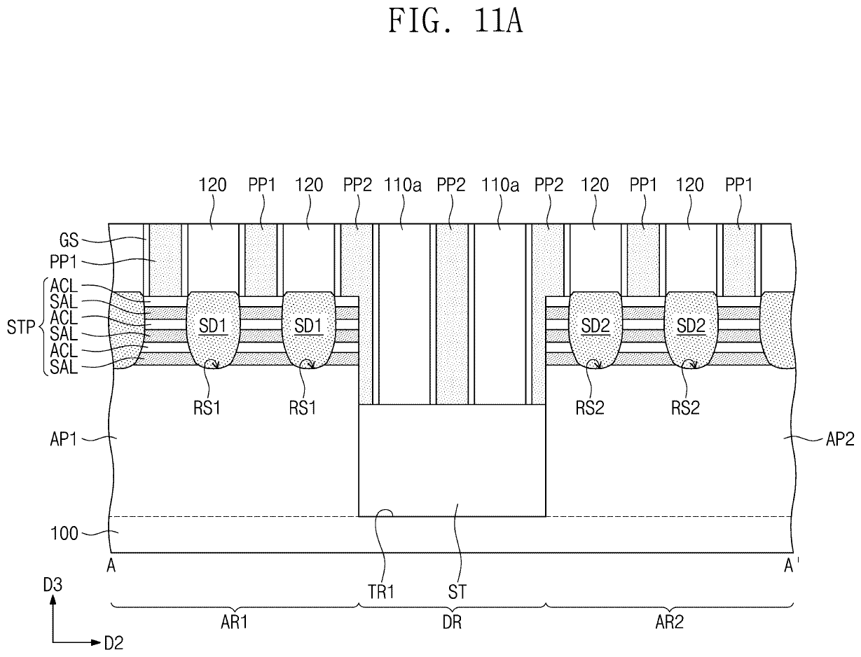

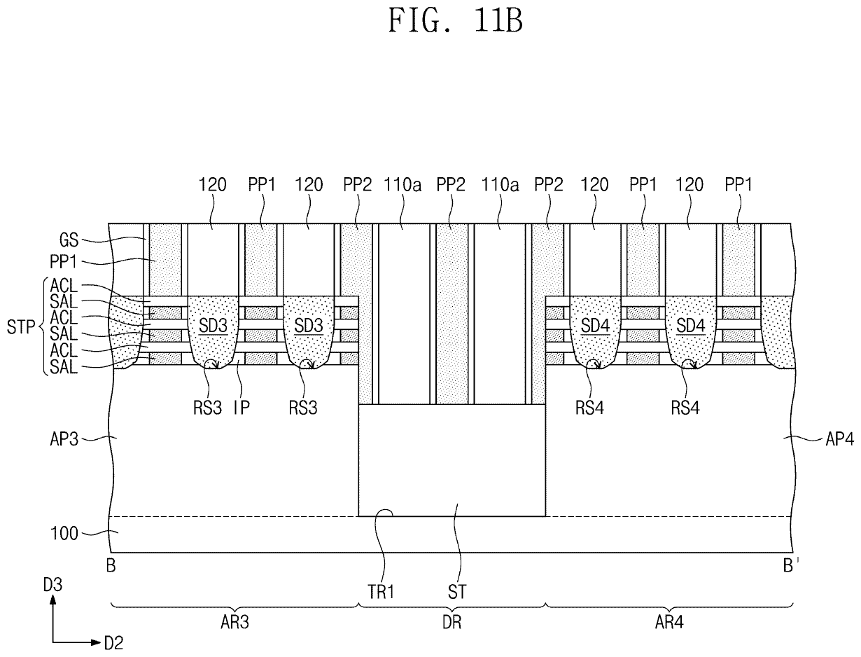

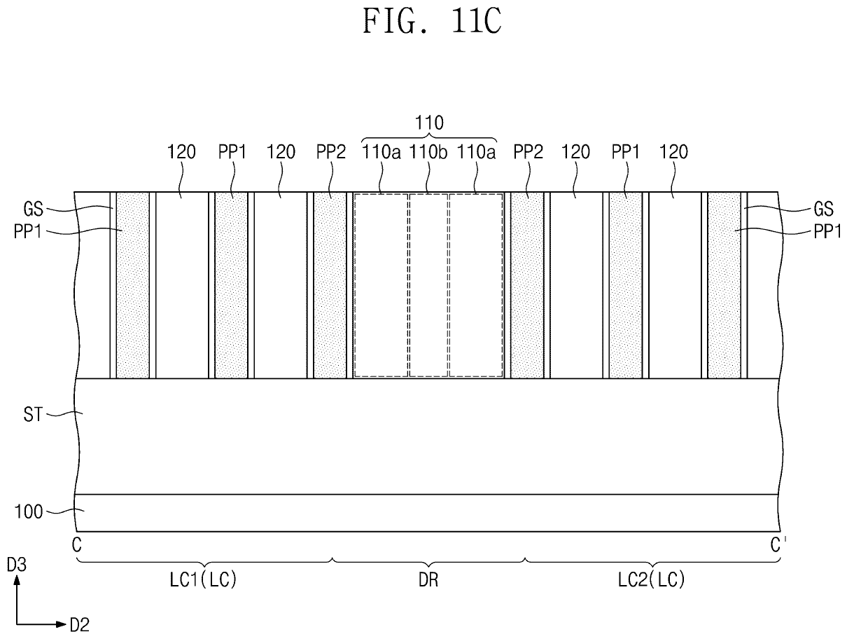

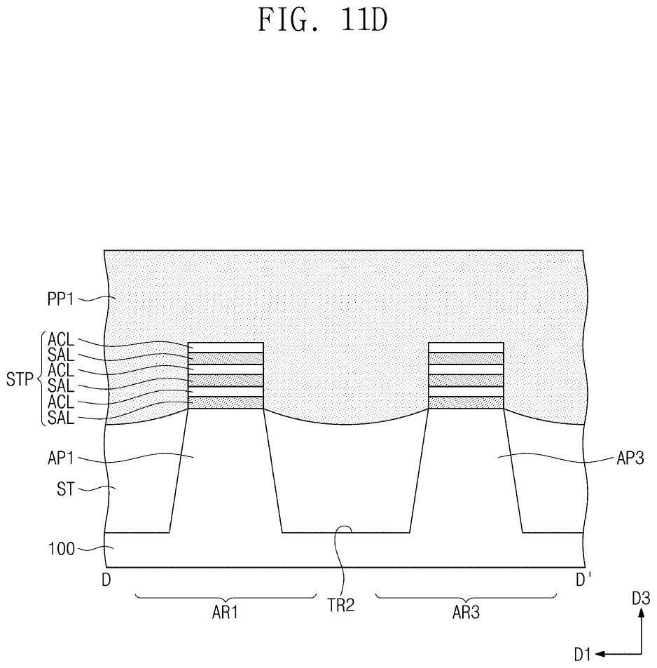

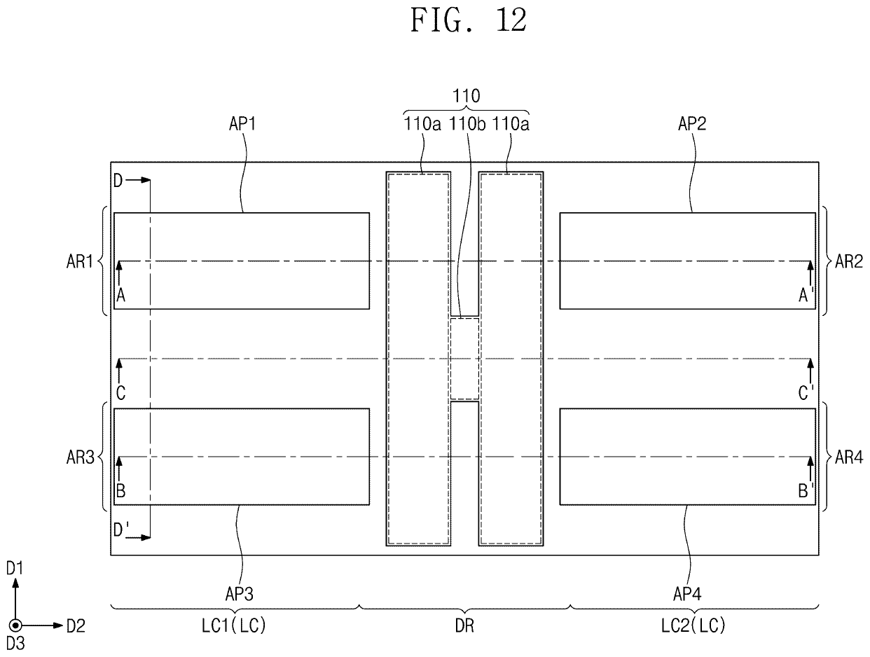

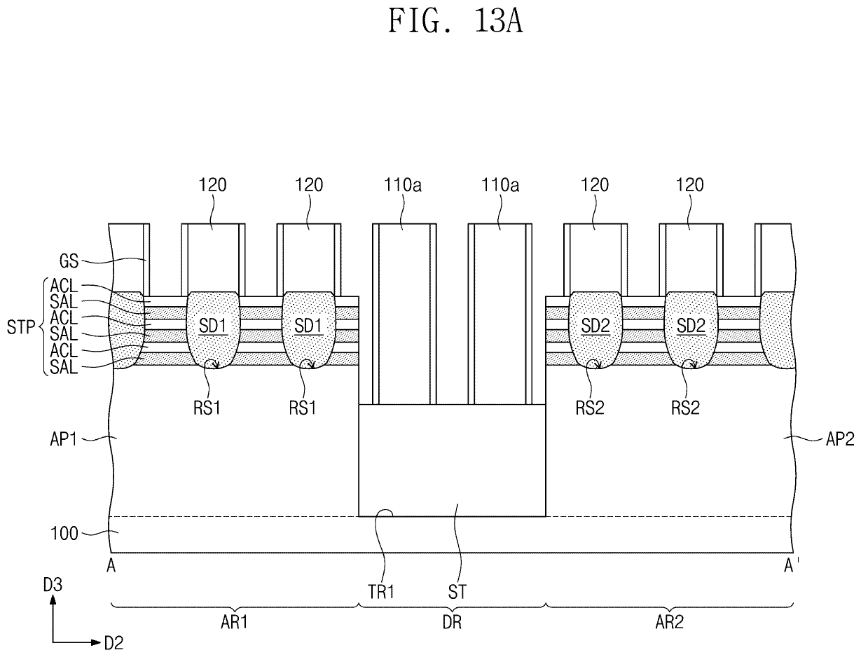

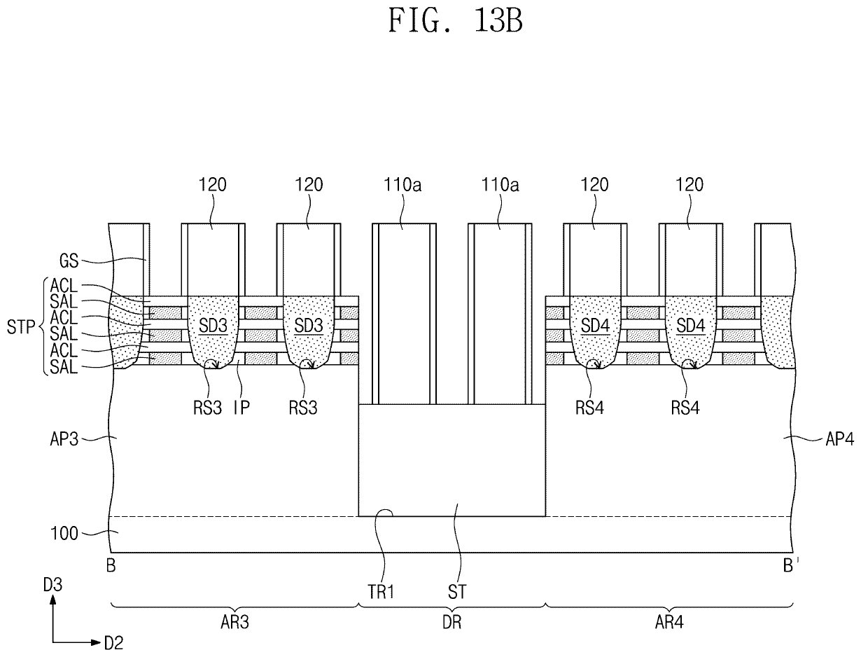

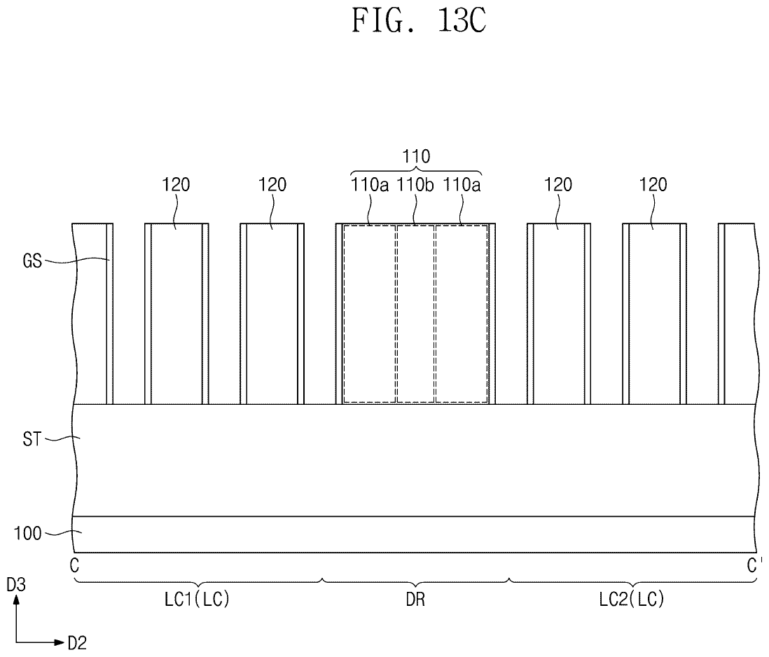

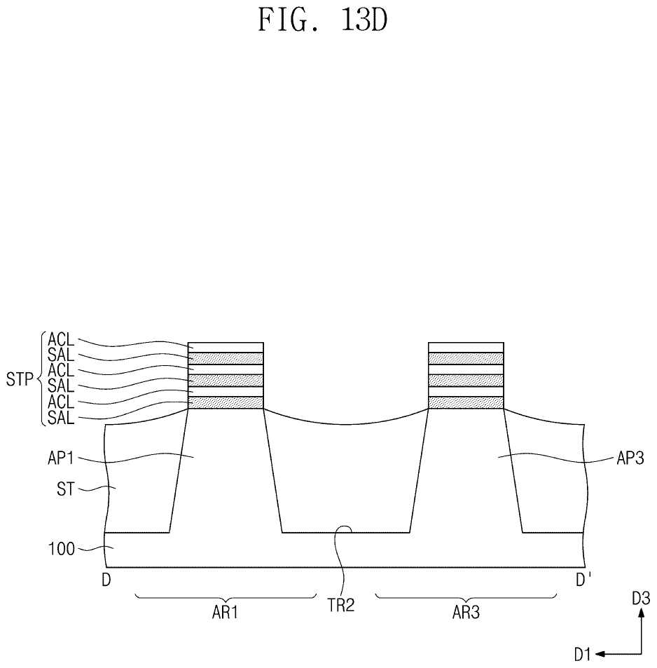

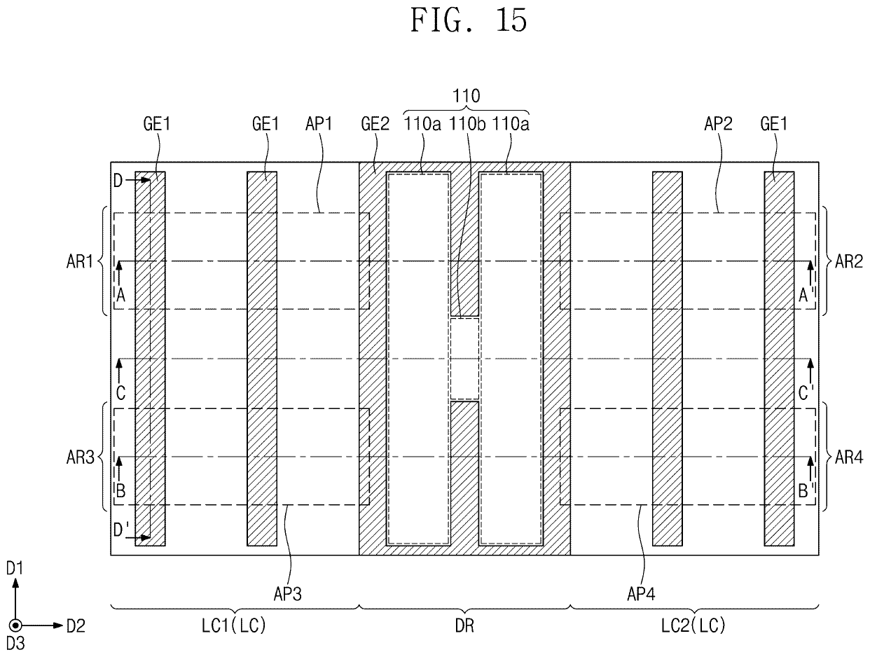

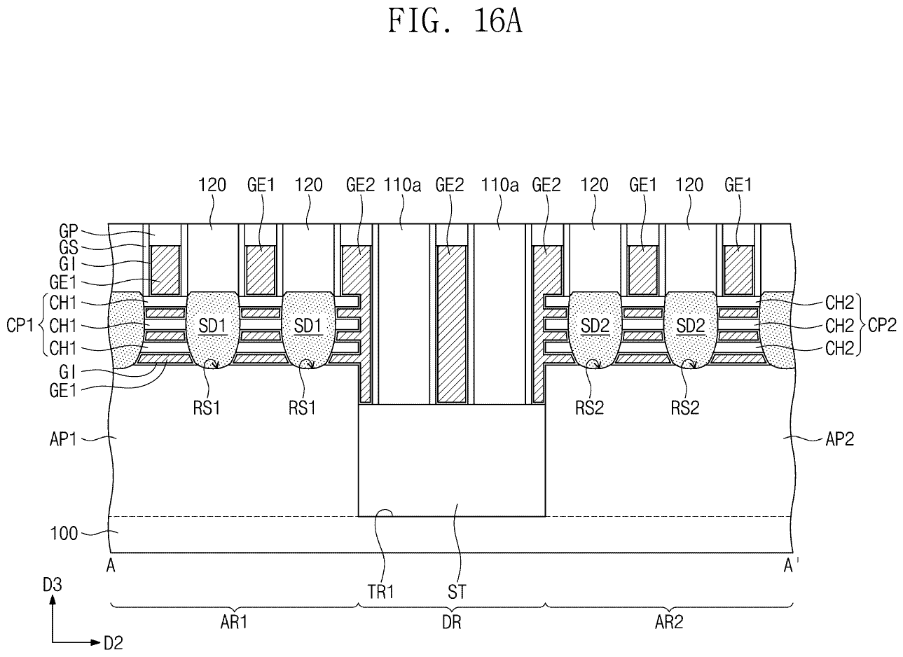

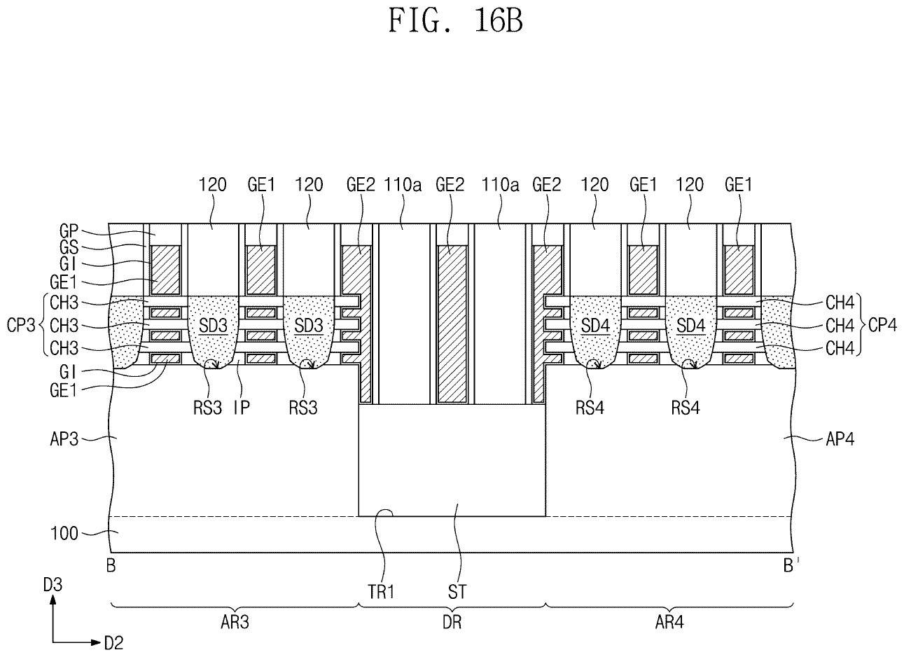

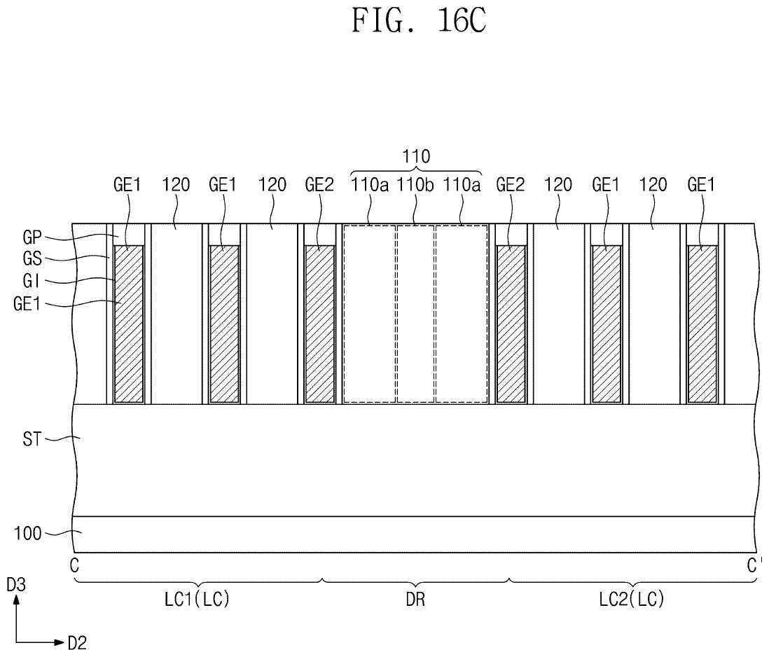

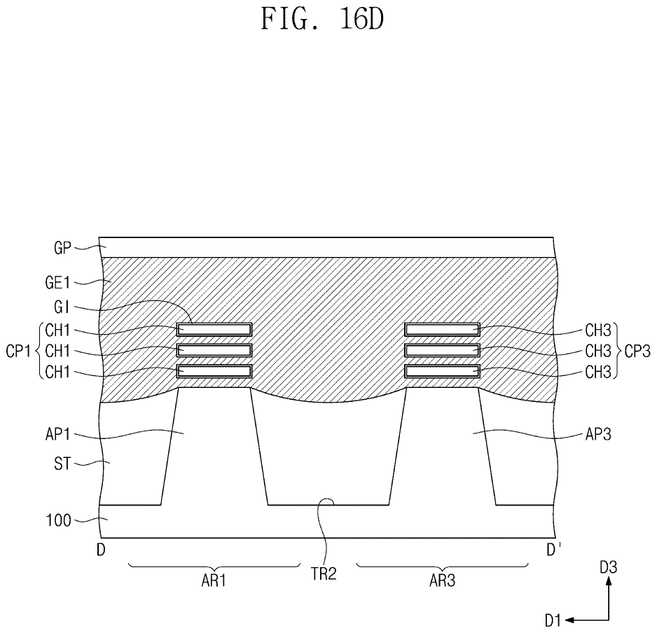

Specifically, FIG. 6, FIG. 10, FIG. 12, and FIG. 15 are plan views corresponding to FIG. 1. FIGS. 7A to 7D which is taken along lines A-A′, B-B′, C-C′, and D-D′ of FIG. 6, respectively. FIGS. 11A to 11D are cross-sections view which is taken along lines A-A′, B-B′, C-C′, and D-D′ of FIG. 10. FIGS. 13A to 13D are cross-sections view which is taken along lines A-A′, B-B′, C-C′, and D-D′ of FIG. 12. FIGS. 16A to 16D are cross-sectional views which is taken along lines A-A′, B-B′, C-C′, and D-D′ of FIG. 15.

Referring to FIGS. 5A-5D, a substrate 100 may be provided. A stacked pattern STP in which sacrificial layers SAL and active layers ACL are alternately stacked may be formed on the substrate 100. For example, the sacrificial layers SAL may include one of silicon (Si), germanium (Ge), or silicon-germanium (SiGe), and the active layers ACL may include another one of silicon (Si), germanium (Ge), or silicon-germanium (SiGe).

For example, the substrate 100 may be a semiconductor substrate including one of silicon (Si), germanium (Ge), and silicon-germanium (SiGe), or a compound semiconductor substrate. For example, the substrate 100 may be a silicon wafer.

First to fourth active patterns AP1, AP2, AP3, and AP4 may be formed by performing a patterning process on the stacked pattern STP and the substrate 100. Performing the patterning process may include forming a first trench TR1 extending in a first direction D1 and forming a second trench TR2 extending in a second direction D2. The first trench TR1 may be formed on a separation region DR. The first trench TR1 may be formed between the first active pattern AP1 and the second active pattern AP2, and between the third active pattern AP3 and the fourth active pattern AP4. The second trench TR2 may be formed between the first active pattern AP1 and the third active pattern AP3, and between the second active pattern AP2 and the fourth active pattern AP4.

A device isolation layer ST filling the first and second trenches TR1 and TR2 may be formed on the substrate 100. Forming the device isolation layer ST may include forming an insulating layer on the substrate 100 and recessing the insulating layer to expose the stacked pattern STP.

Referring to FIGS. 6 and 7A-7D, first and second sacrificial patterns PP1 and PP2 may be formed on the substrate 100. Specifically, the first sacrificial patterns PP1 extending in the first direction D1 may be formed on the first cell region LC1 and the second cell region LC2. The first sacrificial patterns PP1 may cross the first to fourth active patterns AP1, AP2, AP3, and AP4 along the first direction D1. The first sacrificial patterns PP1 may be formed in a line shape or a bar shape extending in the first direction D1. The first sacrificial patterns PP1 may be spaced apart from each other along the second direction D2.

The second sacrificial pattern PP2 may be formed on the separation region DR. The second sacrificial pattern PP2 may be disposed on the device isolation layer ST of the separation region DR. For example, a portion of the second sacrificial pattern PP2 may vertically overlap the first to fourth active patterns AP1, AP2, AP3, and AP4, but is not limited thereto.

An inner wall of the second sacrificial pattern PP2 may define an inner region INR on the separation region DR. In other words, the second sacrificial pattern PP2 may not be provided on the inner region INR, and an upper surface of the device isolation layer ST may be exposed on the inner region INR. For example, the inner region INR may have an H-shape in a plan view, but is not limited thereto.

Forming the first and second sacrificial patterns PP1 and PP2 may include forming a sacrificial layer on the substrate 100, forming mask patterns MP on the sacrificial layer, and patterning the sacrificial layer with the mask patterns MP as an etch mask. The sacrificial layer may comprise polysilicon. The mask patterns MP may include a silicon oxide layer, a silicon nitride layer, or a silicon oxynitride layer.

A pair of gate spacers GS may be formed on both sidewalls of each of the first and second sacrificial patterns PP1 and PP2. For example, the gate spacers GS may include at least one of SiCN, SiCON, or SiN.

The gate spacers GS on the separation region DR may be disposed on the sidewalls of the second sacrificial pattern PP2 and provided on the device isolation layer ST on the separation region DR. The gate spacers GS on the separation region DR may cover a part of the upper surface of the device separation layer ST on the separation region DR.

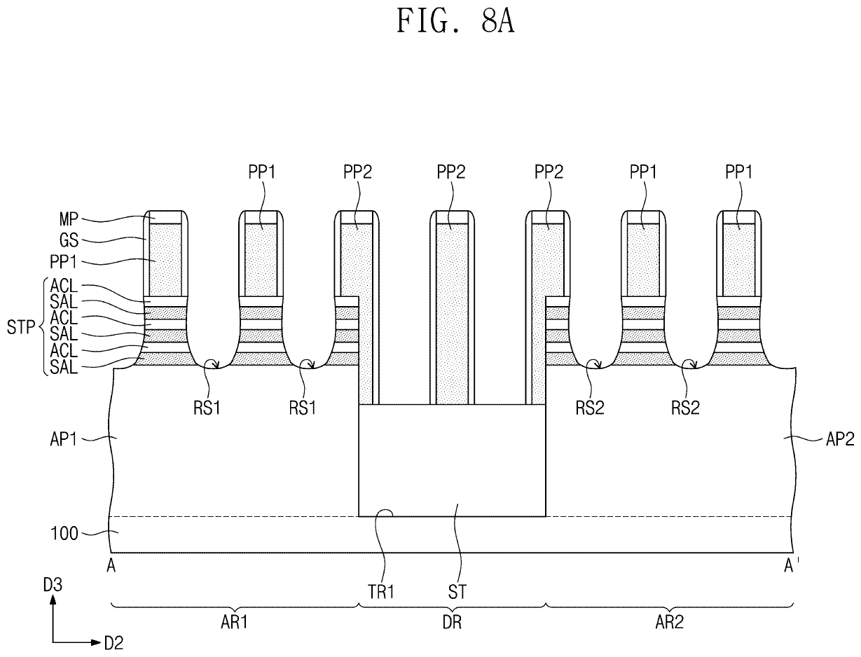

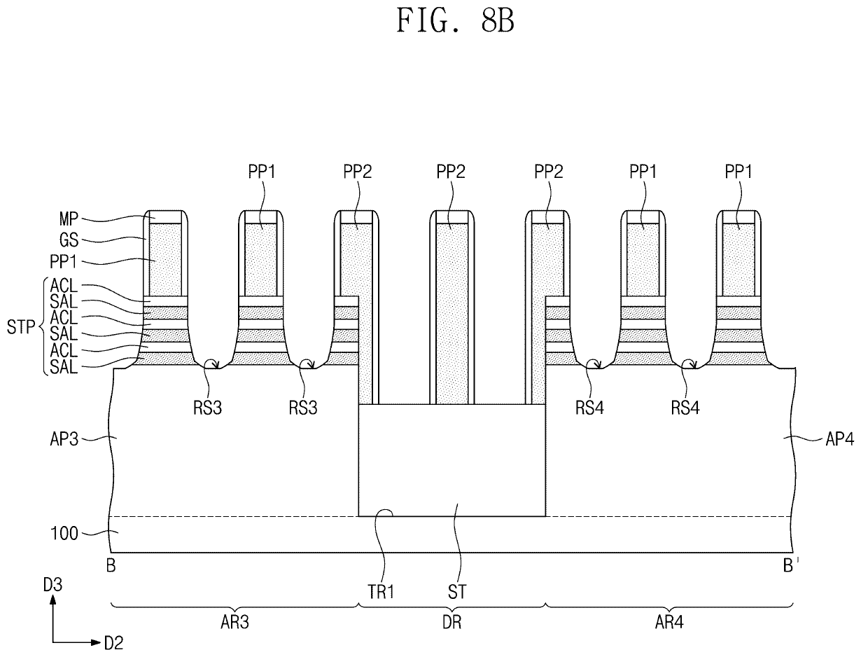

Referring to FIGS. 8A and 8B, a first recess RS1 may be formed in the stacked pattern STP on the first active pattern AP1. A second recess RS2 may be formed in the stacked pattern STP on the second active pattern AP2. A third recess RS3 may be formed in the stacked pattern STP on the third active pattern AP3. A fourth recess RS4 may be formed in the stacked pattern STP on the fourth active pattern AP4.

The first to fourth recesses RS1, RS2, RS3, and RS4 may be formed by etching the stacked pattern STP using the mask patterns MP and the gate spacers GS as an etching mask. Each of the first to fourth recesses RS1, RS2, RS3, and RS4 may be formed between a pair of the first or second sacrificial patterns PP1 and PP2.

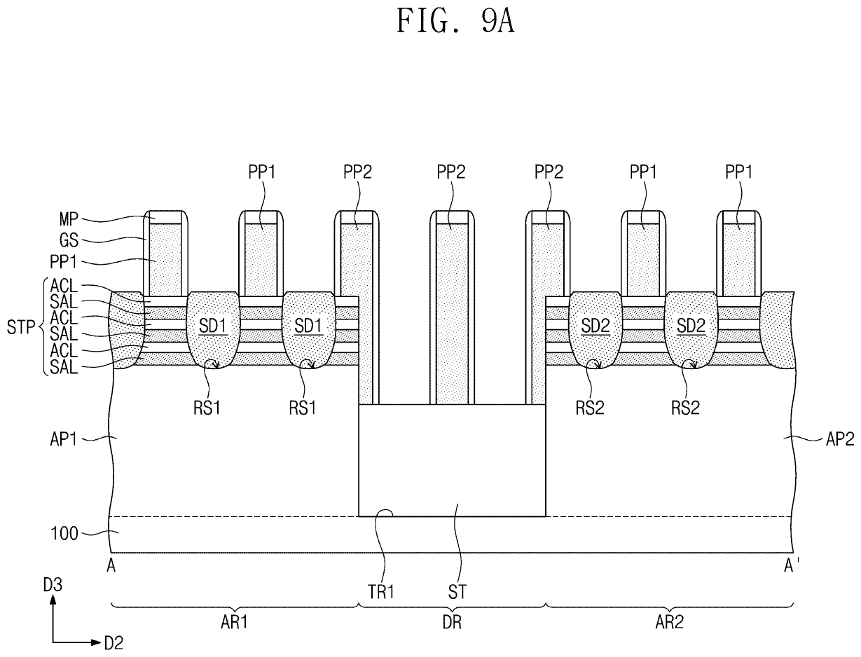

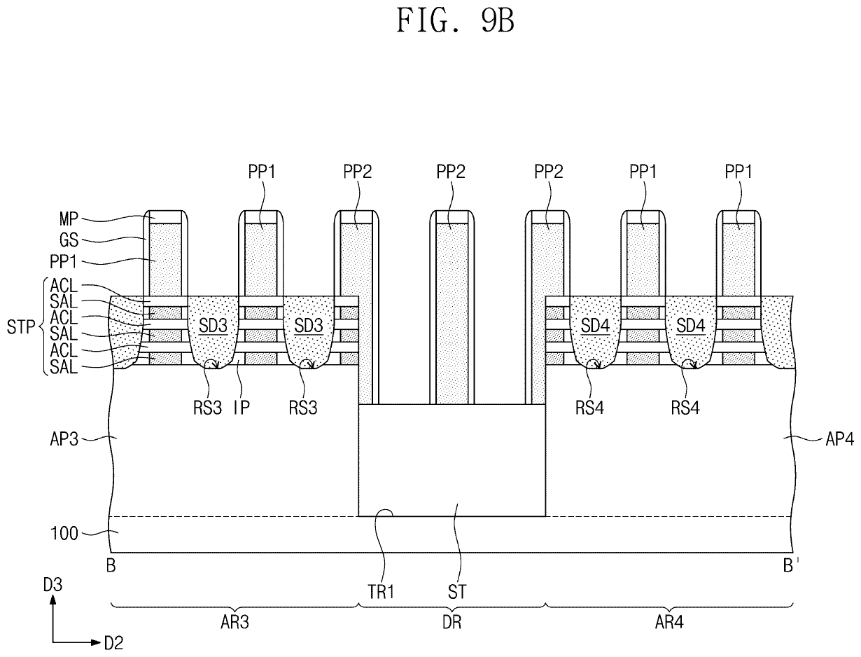

Referring to FIGS. 9A and 9B, a portion of the sacrificial layer SAL exposed through the third and fourth recesses RS2 and RS4 may be replaced with an insulating material to form inner spacers IP.

A first source/drain pattern SD1 may be formed in the first recess RS1. Forming the first source/drain pattern SD1 may include performing a selective epitaxial process with an inner wall of the first recess RS1 as a seed layer. For example, the selective epitaxial process may include a chemical vapor deposition (CVD) process or a molecular beam epitaxy (MBE) process.

For example, the first source/drain pattern SD1 may be formed of a semiconductor element (e.g., SiGe) having a lattice constant greater than that of the semiconductor element of the substrate 100. Simultaneously with or after the selective epitaxial process, the first source/drain pattern SD1 may be doped with p-type impurities.

A second source/drain pattern SD2 may be formed in the second recess RS2. Forming the second source/drain pattern SD2 may be substantially the same as forming the first source/drain pattern SD1.

A third source/drain pattern SD3 may be formed in the third recess RS3. Forming the third source/drain pattern SD3 may include performing a selective epitaxial process with an inner wall of the third recess RS3 as a seed layer. As an example, the third source/drain pattern SD3 may be formed of the same semiconductor element (e.g., Si) as the substrate 100. Simultaneously with or after the selective epitaxial process, the third source/drain pattern SD3 may be doped with n-type impurities.

A fourth source/drain pattern SD4 may be formed in the fourth recess RS4. Forming the fourth source/drain pattern SD4 may be substantially the same as forming the third source/drain pattern SD3.

Referring to FIGS. 10 and 11A to 11D, a first interlayer insulating layer 120 filling between the first sacrificial patterns PP1 and a first insulation pattern 110 filling the inner region INR (see in FIG. 6) defined by the inner wall of the second sacrificial pattern PP2 may be formed. The first interlayer insulating layer 120 may cover the first to fourth source/drain patterns SD1, SD2, SD3, and SD4 on the cell region LC. The first insulation pattern 110 may cover the device isolation layer ST on the separation region DR. For example, the first interlayer insulating layer 120 and the first insulation pattern 110 may include at least one of silicon oxide, silicon nitride, or silicon oxynitride.

In a plan view, the second sacrificial pattern PP2 may surround the first insulation pattern 110. The first insulation pattern 110 may include first extension portions 110a and a first connection portion 110b connecting the first extension portions 110a. The first extension portions 110a of the first insulation pattern 110 may extend in the first direction D1 and may be spaced apart from each other along the second direction D2. For example, the first extension portions 110a may be disposed in parallel along the second direction D2.

Forming the first insulation pattern 110 and the first interlayer insulating layer 120 may include forming an insulating layer covering the first to fourth source/drain patterns SD1, SD2, SD3, and SD4, the mask patterns MP (see FIG. 9A), the gate spacers GS, and the device isolation layer ST, and planarizing the insulating layer to expose top surfaces of the first and second sacrificial patterns PP1 and PP2 (see FIG. 9a). The planarization of the insulating layer may be performed using an Etch Back or a CMP (Chemical Mechanical Polishing) process. During the planarization process, all of the mask patterns MP (see FIG. 9A) may be removed. As a result, top surfaces of the first insulation pattern 110 and the first interlayer insulating layer 120 may be coplanar with top surfaces of first and second sacrificial patterns PP1 and PP2 (see FIG. 9A) and top surfaces of gate spacers GS.

Referring to FIGS. 10, 11A-11D, 12, and 13A-13D, the first and second sacrificial patterns PP1, PP2 may be selectively removed. Removing the first and second sacrificial patterns PP1, PP2 may include wet etching using an etchant that selectively etches the polysilicon. As the first and second sacrificial patterns PP1 and PP2 are removed, the stacked pattern STP between the gate spacers GS and the device isolation layer ST may be partially exposed. In other words, the active layers ACL and the sacrificial layers SAL of the stacked pattern STP may be exposed.

For example, if the first insulation pattern 110 on the separation region DR has a line shape or a bar shape extending in the first direction D1, after the first and second sacrificial patterns PP1 and PP2 are removed, the first insulation pattern 110 may be unstable due to a high aspect ratio of the first insulation pattern 110. For example, the first insulation pattern 110 may be tilted, and it may result in manufacturing failure of a semiconductor device.

However, according to an embodiment of the present application, the first insulation pattern 110 including the first extension portions 110a extending in the first direction D1 and the connection portion 110b connecting the first extension portions 110a may be provided. Due to a structure of the first insulation pattern 110, the structural stability can be improved. Accordingly, it is possible to prevent the first insulation pattern 110 from leaning in a process of manufacturing the semiconductor device. In addition, since the second sacrificial pattern PP2 is also not formed in a line shape or a bar shape extending in the first direction D1, structural stability of the second sacrificial pattern PP2 may be improved. Accordingly, a reliability of the semiconductor device can be improved.

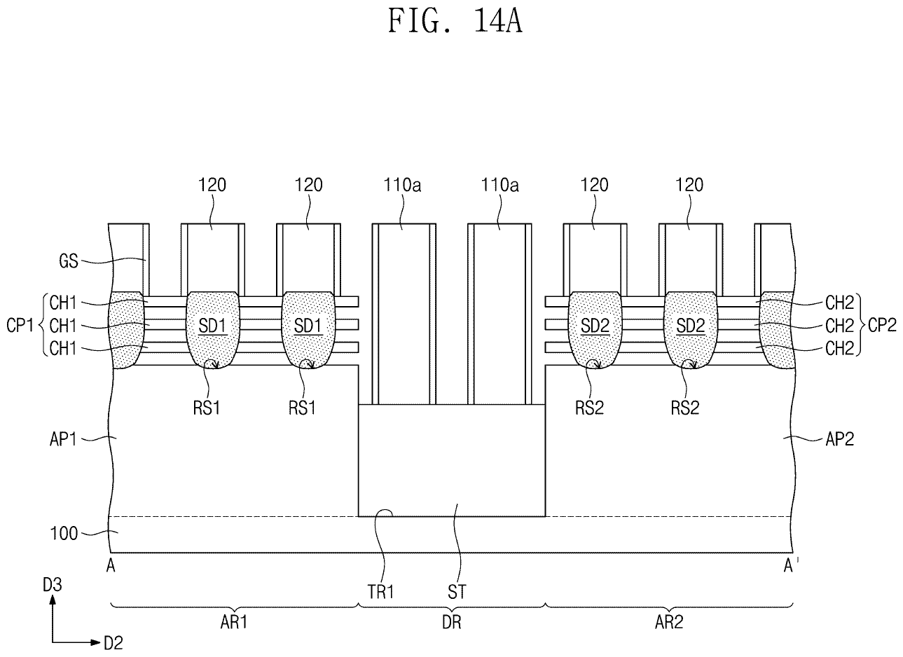

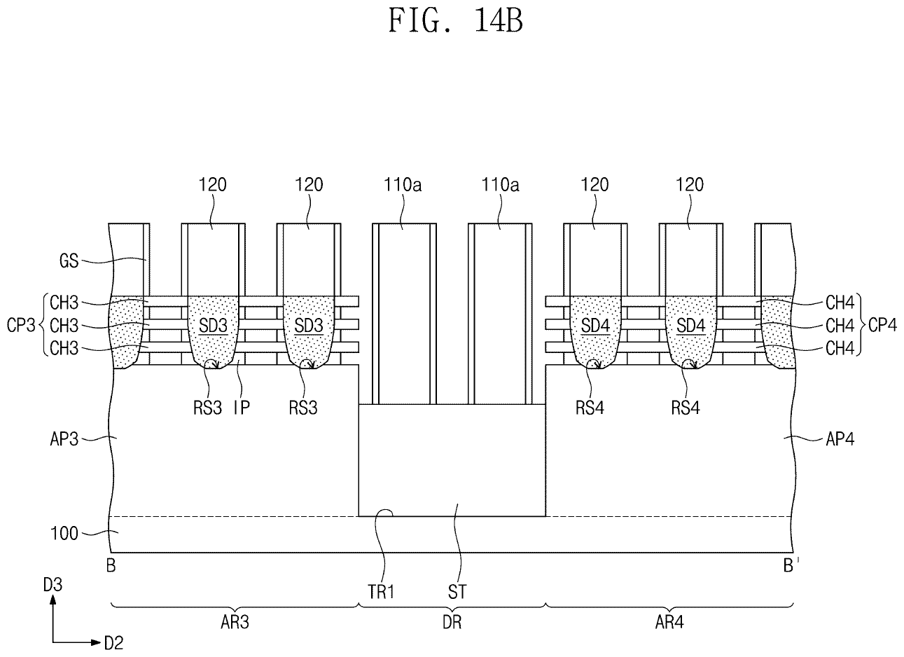

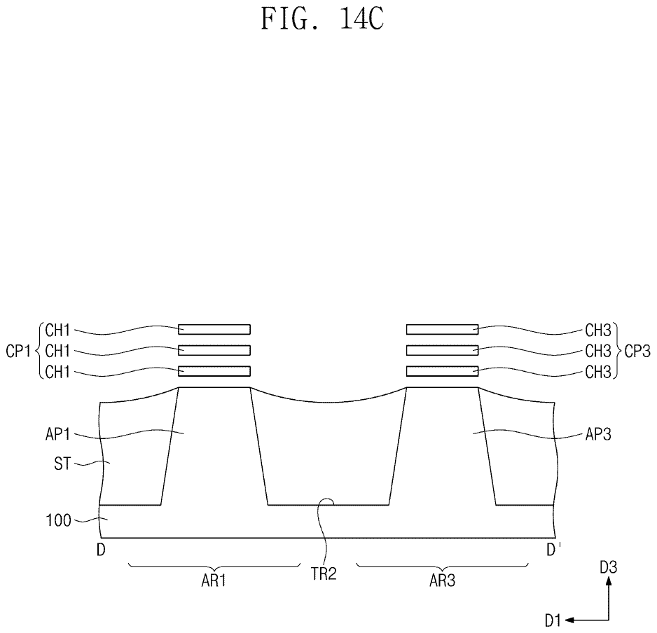

Referring to FIGS. 13A-13D and 14A-14C, the exposed sacrificial layers SAL may be selectively removed. An etching process of selectively etching the sacrificial layers SAL may be performed to remove only the sacrificial layers SAL without removing the active layers ACL.

The active layers ACL vertically stacked between adjacent first source/drain patterns SD1 may be referred to as first semiconductor patterns CH1. The vertically stacked first semiconductor patterns CH1 may be referred to as a first channel pattern CP1. The active layers ACL vertically stacked between adjacent second source/drain patterns SD2 may be referred to as second semiconductor patterns CH2. The vertically stacked second semiconductor patterns CH2 may be referred to as a second channel pattern CP2. The active layers ACL vertically stacked between adjacent third source/drain patterns SD3 may be referred to as third semiconductor patterns CH3. The vertically stacked third semiconductor patterns CH3 may be referred to as a third channel pattern CP3. The active layers ACL vertically stacked between adjacent fourth source/drain patterns SD4 may be referred to as fourth semiconductor patterns CH4. The vertically stacked fourth semiconductor patterns CH4 may be referred to as a fourth channel pattern CP4.

Referring to FIGS. 15 and 16A to 16D, a gate insulating layer GI may be conformally formed on the exposed first to fourth semiconductor patterns CH1, CH2, CH3, and CH4 and the device isolation layer ST. The gate insulating layer GI may cover a portion of an upper surface of the device isolation layer ST on the separation region DR. For example, the gate insulating layer GI may include a silicon oxide layer, a silicon oxynitride layer, and/or a high dielectric layer.

The first and second gate electrodes GE1 and GE2 may be formed on the gate insulating layer GI. The first gate electrodes GE1 may fill a space exposed by removing the first sacrificial patterns PP1 (see FIG. 11A). The second gate electrode GE2 may fill a space exposed by removing the second sacrificial pattern PP2 (see FIG. 11A).

The second gate electrode GE2 may surround the first insulation pattern 110 in a plan view. The second gate electrode GE2 may fill a space between the first extension portions 110a of the first insulation pattern 110. A portion of the second gate electrode GE2 may be formed to be interposed between the first to fourth semiconductor patterns CH1, CH2, CH3, and CH4 adjacent to the separation region DR. As an example, the first and second gate electrodes GE1, GE2 may include at least one of a conductive metal nitride (e.g., titanium nitride or tantalum nitride) or a metal material (e.g., titanium, tantalum, tungsten, copper, or aluminum).

A gate capping pattern GP may be formed on the first and second gate electrodes GE1 and GE2. As an example, the gate capping pattern GP may include at least one of SiON, SiCN, SiCON, or SiN.

Referring back to FIGS. 1 and 2A to 2D, a second interlayer insulating layer 130 may be formed on the first interlayer insulating layer 120 and the first insulation pattern 110. An active contact AC electrically connected to the first to fourth source/drain patterns SD1, SD2, SD3, and SD4 through the first and second interlayer insulating layers 120 and 130 may be formed. A gate contact GC electrically connected to the first gate electrodes GE1 through the second interlayer insulating layer 130 and the gate capping pattern GP may be formed.

A third interlayer insulating layer 140 may be formed on the active contact AC and the gate contact GC. First wirings M1 and first vias VI1 may be formed in the third interlayer insulating layer 140.

According to embodiments of the invention, an insulation pattern comprising extension portions extending in a first direction and a connection connecting them on a separation region of a substrate may be provided. Since the insulation pattern further includes a connection portion connecting the extension portions to each other, structural stability of the insulation pattern can be improved. Accordingly, it is possible to prevent the insulation pattern from leaning in a process of manufacturing a semiconductor device. Furthermore, a reliability of the semiconductor device can be improved.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate including a separation region extending in a first direction;
a first active pattern and a second active pattern on the substrate, the first active pattern and the second active pattern being spaced apart from each other in a second direction perpendicular to the first direction with the separation region therebetween;
first gate electrodes crossing the first active pattern and the second active pattern and extending in the first direction; and
a first insulation pattern horizontally spaced apart from the first gate electrodes and provided on the separation region,
wherein the first insulation pattern comprises:
first extension portions extending in the first direction and spaced apart from each other along the second direction; and
a first connection portion provided between the first extension portions and connecting the first extension portions to each other.

2. The semiconductor device of claim 1, further comprising:
a second gate electrode provided on the separation region; and
a gate dielectric layer between the second gate electrode and the first insulation pattern,
wherein the second gate electrode surrounds the first insulation pattern in a plan view.

3. The semiconductor device of claim 2, wherein the second gate electrode is interposed between the first extension portions.

4. The semiconductor device of claim 1, further comprising:
a gate capping pattern on the first gate electrodes,
wherein an upper surface of the first insulation pattern is coplanar with an upper surface of the gate capping pattern.

5. The semiconductor device of claim 1,
wherein lengths of the first extension portions along the first direction are greater than a length of the first connection portion along the first direction.

6. The semiconductor device of claim 1,
wherein the first connection portion extends along the second direction.

7. The semiconductor device of claim 1,
wherein the first connection portion extends along a third direction, the third direction forming an acute angle with the first direction and the second direction and being parallel to a lower surface of the substrate.

8. The semiconductor device of claim 1, further comprising:
a first channel pattern including first semiconductor patterns vertically stacked and spaced apart from each other on the first active pattern; and
a second channel pattern including second semiconductor patterns vertically stacked and spaced apart from each other on the second active pattern,
wherein the first gate electrodes surround the first channel pattern and the second channel pattern.

9. The semiconductor device of claim 1,
wherein top surfaces of the first extension portions and top surface of the first connection portion are coplanar with each other.

10. The semiconductor device of claim 1,
wherein the first insulation pattern has an H shape in a plan view.

11. The semiconductor device of claim 1, further comprising:
a device isolation layer defining the first active pattern and the second active pattern,
wherein the first insulation pattern is disposed on the device isolation layer.

12. A semiconductor device, comprising:
a substrate including a separation region extending in a first direction;
a first active pattern and a second active pattern on the substrate, the first active pattern and the second active pattern being spaced apart from each other in a second direction perpendicular to the first direction with the separation region therebetween;
first gate electrodes crossing the first active pattern and the second active pattern and extending in the first direction;
a plurality of insulation patterns provided on the separation region and spaced apart from each other; and
a second gate electrode provided on the separation region and surrounding the plurality of insulation patterns in a plan view,
wherein each of the plurality of insulation patterns comprises:
extension portions extending in the first direction and spaced apart from each other along the second direction; and
a connection portion provided between the extension portions and connecting the extension portions to each other.

13. The semiconductor device of claim 12,
wherein the second gate electrode is spaced apart from the first gate electrodes in the second direction.

14. The semiconductor device of claim 12,
wherein the second gate electrode is interposed between the plurality of insulation patterns.

15. The semiconductor device of claim 12, further comprising:
gate contacts electrically connected to the first gate electrodes,
wherein the gate contacts are not provided on the second gate electrode.

16. The semiconductor device of claim 12,
wherein the second gate electrode is a dummy gate electrode and is not electrically connected to the gate contacts.

17. The semiconductor device of claim 12,
wherein the plurality of insulation patterns includes a first insulation pattern, a second insulation pattern, and a third insulation pattern,
wherein the extension portions of the first insulation pattern are spaced apart from the extension portions of second insulation pattern in the second direction,
wherein the extension portions of the first insulation pattern are spaced apart from extension portions of the third insulation pattern in the first direction.

18. The semiconductor device of claim 17,
wherein lengths of the extension portions of the first insulation pattern along the first direction are greater than a length of the connection portion of the first insulation pattern along the first direction,
wherein lengths of the extension portions of the second insulation pattern along the first direction are greater than a length of the connection portion of the second insulation pattern along the first direction, and
wherein lengths of the extension portions of the third insulation pattern along the first direction are greater than a length of the connection portion of the third insulation pattern along the first direction.

19. The semiconductor device of claim 12, further comprising:
a first channel pattern including first semiconductor patterns vertically stacked and spaced apart from each other on the first active pattern; and
a second channel pattern including second semiconductor patterns vertically stacked and spaced apart from each other on the second active pattern,
wherein the first gate electrodes surround the first channel pattern and the second channel pattern.

20. A semiconductor device, comprising:
a substrate including a separation region extending in a first direction;
a first active pattern and a second active pattern on the substrate, the first active pattern and the second active pattern being spaced apart from each other in a second direction perpendicular to the first direction with the separation region therebetween;
first source/drain patterns provided on the first active pattern;
second source/drain patterns provided on the second active pattern;
a first channel pattern including first semiconductor patterns vertically stacked and spaced apart from each other between the first source/drain patterns;
a second channel pattern including second semiconductor patterns vertically stacked and spaced apart from each other between the second source/drain patterns;
first gate electrodes extending in the first direction on the first channel pattern and the second channel pattern;
active contacts electrically connected with the first source/drain patterns and the second source/drain patterns;
gate contacts electrically connected with the first gate electrodes; and
a first insulation pattern horizontally spaced apart from the first gate electrodes and provided on the separation region,
wherein the first insulation pattern comprises:
first extension portions each extending in the first direction and spaced apart from each other along the second direction; and
a first connection portion provided between the first extension portions and connecting the first extension portions to each other.
